(19) United States
(12) Patent Application Publication
(10) Pub. No.: US 2025/0124102 A1
(43) Pub. Date: Apr. 17, 2025

(54) VECTOR ELEMENT MULTIPLICATION IN NAND MEMORY

(71) Applicant: MICRON TECHNOLOGY, INC., Boise, ID (US)

(72) Inventors: Dmitri Yudanov, Sacramento, CA (US); Lawrence Celso Miranda, San Jose, CA (US); Sheyang Ning, San Jose, CA (US); Aliasger Zaidy, Providence, RI (US)

(73) Assignee: MICRON TECHNOLOGY, INC., Boise, ID (US)

(21) Appl. No.: 18/757,909

(22) Filed: Jun. 28, 2024

Related U.S. Application Data
(60) Provisional application No. 63/590,860, filed on Oct. 17, 2023.

(51) Int. Cl. G06F 17/16

(52) U.S. Cl. CPC G06F 17/16

(57) ABSTRACT

Memories might include a plurality of strings of series-connected memory cells, each corresponding to a respective digit of a plurality of digits of a multiplicand, and might further include a controller configured to cause the memory to generate respective current flows through the plurality of strings of series-connected memory cells for each digit of a plurality of digits of a multiplier having respective current levels indicative of values of each digit of the plurality of digits of the multiplier times the multiplicand, to convert the respective current levels to respective digital values indicative of the values and magnitudes of each digit of the plurality of digits of the multiplier times the multiplicand, and to sum the respective digital value of each digit of the plurality of digits of the multiplier.

### RELATED APPLICATION

This application claims the benefit of U.S. Provisional Application No. 63/590,860, filed on Oct. 17, 2023, hereby incorporated herein in its entirety by reference.

### TECHNICAL FIELD

The present disclosure relates generally to integrated circuits and methods of their operation, and, in particular, in one or more embodiments, the present disclosure relates to memories configured to perform artificial intelligence (AI) computational patterns, e.g., including matrix dot products involving vector element multiplication.

### BACKGROUND

Integrated circuit devices traverse a broad range of electronic devices. One particular type includes memory devices, often referred to simply as memory. Memory devices are typically provided as internal, semiconductor, integrated circuit devices in computers or other electronic devices. There are many different types of memory including random-access memory (RAM), read only memory (ROM), dynamic random access memory (DRAM), synchronous dynamic random access memory (SDRAM), and flash memory.

Flash memory has developed into a popular source of non-volatile memory for a wide range of electronic applications. Flash memory typically use a one-transistor memory cell that allows for high memory densities, high reliability, and low power consumption. Changes in threshold voltage (Vt) of the memory cells, through programming (which is often referred to as writing) of charge storage nodes (e.g., floating gates or charge traps) or other physical phenomena (e.g., phase change or polarization), determine the data state (e.g., data value) of each memory cell. Common uses for flash memory and other non-volatile memory include personal computers, personal digital assistants (PDAs), digital cameras, digital media players, digital recorders, games, appliances, vehicles, wireless devices, mobile telephones, and removable memory modules, and the uses for non-volatile memory continue to expand.

A NAND flash memory is a common type of flash memory device, so called for the logical form in which the basic memory cell configuration is arranged. Typically, the array of memory cells for NAND flash memory is arranged such that the control gate of each memory cell of a row of the array might be connected together to form an access line, such as a word line. Columns of the array include strings (often termed NAND strings) of memory cells connected together in series between a pair of select gates, e.g., a source select transistor and a drain select transistor. Each source select transistor might be connected to a source, while each drain select transistor might be connected to a data line, such as column bit line. Variations using more than one select gate between a string of memory cells and the source, and/or between the string of memory cells and the data line, are known.

An Artificial Neural Network (ANN) might use a network of neurons to process inputs to the network and to generate outputs from the network. In general, an ANN might be trained using supervised and/or unsupervised methods.

Deep learning might use multiple layers of machine learning to progressively extract features from input data, and might be implemented via ANNs, such as deep neural networks, deep belief networks, recurrent neural networks, and/or convolutional neural networks. Deep learning has been applied to many application fields, such as computer vision, speech/audio recognition, natural language processing, machine translation, bioinformatics, drug design, medical image processing, games, etc.

### BRIEF DESCRIPTION OF THE DRAWINGS

FIG. 1 is a simplified block diagram of a memory in communication with a processor as part of an electronic system, according to an embodiment.

FIGS. 2A-2B are schematics of a portion of an array of memory cells in accordance with an embodiment.

FIGS. 3A-3D depict a Deep Learning Accelerator connected to a host, as well as various processing units that might be used in the Deep Learning Accelerator.

FIG. 4 depicts a matrix-matrix unit.

FIG. 5 details the computations of a matrix-matrix unit.

FIGS. 6A and 6B depict portions of an array of memory cells configured to store digits of a multiplicand in an analog fashion and a binary fashion, respectively, in accordance with embodiments.

FIG. 7 depicts a portion of an array of memory cells having a block of memory cells for use in discussing arithmetic operations in accordance with embodiments.

FIGS. 8A-8F depict registers during a multiply-accumulate operation in accordance with an embodiment.

FIGS. 9A-9F depict registers during a multiply-accumulate operation in accordance with another embodiment.

FIGS. 10-12 might represent characterizations of current flow as a function of relevant variables.

FIG. 13 is a flowchart of a method of operating a memory in accordance with an embodiment.

FIG. 14 is a flowchart of a method of operating a memory in accordance with a further embodiment.

FIG. 15 is a flowchart of a method of operating a memory in accordance with a still further embodiment.

FIG. 16A is a flowchart of a method of operating a memory in accordance with a still further embodiment.

FIG. 16B is a flowchart of a method of operating a memory in accordance with an alternate embodiment.

FIG. 17 depicts a portion of an array of memory cells having more than one block of memory cells in accordance with an embodiment.

### DETAILED DESCRIPTION

In the following detailed description, reference is made to the accompanying drawings that form a part hereof, and in which is shown, by way of illustration, specific embodiments. In the drawings, like reference numerals describe substantially similar components throughout the several views. Other embodiments might be utilized and structural, logical and electrical changes might be made without departing from the scope of the present disclosure. The following detailed description is, therefore, not to be taken in a limiting sense.

The term “conductive” as used herein, as well as its various related forms, e.g., conduct, conductively, conducting, conduction, conductivity, etc., refers to electrically conductive unless otherwise apparent from the context. Similarly, the term “connecting” as used herein, as well as its various related forms, e.g., connect, connected, connection, etc., refers to electrically connecting by a conductive path unless otherwise apparent from the context.

As used herein, multiple acts being performed concurrently will mean that each of these acts is performed for a respective time period, and each of these respective time periods overlaps, in part or in whole, with each of the remaining respective time periods. In other words, portions of each of those acts are simultaneously performed for at least some period of time.

Unless otherwise defined, directional references such as upper, top, lower, bottom, side, left, right, parallel, orthogonal, etc. used in the description of the figures refers to such directions relative to the orientation of the figure itself.

It is recognized herein that even where values might be intended to be equal, variabilities and accuracies of industrial processing and operation might lead to differences from their intended values. These variabilities and accuracies will generally be dependent upon the technology utilized in fabrication and operation of the integrated circuit device. As such, if values are intended to be equal, those values are deemed to be equal regardless of their resulting values.

An Artificial Neural Network (ANN) might use a network of neurons to process inputs to the network and to generate outputs from the network. For example, each neuron in the network might receive a set of inputs. Some of the inputs to a neuron might be the outputs of certain neurons in the network; and some of the inputs to a neuron might be the inputs provided to the neural network. The input/output relations among the neurons in the network represent the neuron connectivity in the network.

Each neuron might have a bias, an activation function, and a set of synaptic weights for its inputs respectively. The activation function might be in the form of a step function, a linear function, a log-sigmoid function, etc. Different neurons in the network might have different activation functions.

Each neuron might generate a weighted sum of its inputs and its bias and then produce an output that is the function of the weighted sum, computed using the activation function of the neuron.

The relations between the input(s) and the output(s) of an ANN in general might be defined by an ANN model that includes the data representing the connectivity of the neurons in the network, as well as the bias, activation function, and synaptic weights of each neuron. Based on a given ANN model, a computing device can be configured to compute the output(s) of the network from a given set of inputs to the network.

For example, the inputs to an ANN might be generated based on camera inputs; and the outputs from the ANN might be the identification of an item, such as an event or an object.

In general, an ANN might be trained using a supervised method where the parameters in the ANN are adjusted to minimize or reduce the error between known outputs associated with or resulted from respective inputs and computed outputs generated via applying the inputs to the ANN. Examples of supervised learning/training methods include reinforcement learning and learning with error correction.

Alternatively, or in combination, an ANN might be trained using an unsupervised method where the exact outputs resulted from a given set of inputs is not known before the completion of the training. The ANN can be trained to classify an item into a plurality of categories, or data points into clusters. Multiple training algorithms can be employed for a sophisticated machine learning/training paradigm.

Deep learning might use multiple layers of machine learning to progressively extract features from input data. For example, lower layers can be configured to identify edges in an image; and higher layers can be configured to identify, based on the edges detected using the lower layers, items captured in the image, such as faces, objects, events, etc. Deep learning can be implemented via ANNs, such as deep neural networks, deep belief networks, recurrent neural networks, and/or convolutional neural networks.

Deep learning has been applied to many application fields, such as computer vision, speech/audio recognition, natural language processing, machine translation, bioinformatics, drug design, medical image processing, games, etc.

The granularity of the DLA operating on vectors and matrices corresponds to the largest unit of vectors/matrices that can be operated upon during the execution of one instruction by the DLA. During the execution of the instruction for a predefined operation on vector/matrix operands, elements of vector/matrix operands can be operated upon by the DLA in parallel to reduce execution time and/or energy consumption associated with memory/data access. The operations on vector/matrix operands of the granularity of the DLA can be used as building blocks to implement computations on vectors/matrices of larger sizes.

The implementation of a typical/practical ANN involves vector/matrix operands having sizes that are larger than the operation granularity of the DLA. To implement such an ANN using the DLA, computations involving the vector/matrix operands of large sizes can be broken down to the computations of vector/matrix operands of the granularity of the DLA. The DLA can be programmed via instructions to carry out the computations involving large vector/matrix operands. For example, atomic computation capabilities of the DLA in manipulating vectors and matrices of the granularity of the DLA in response to instructions can be programmed to implement computations in an ANN.

In some implementations, the DLA lacks some of the logic operation capabilities of a typical Central Processing Unit (CPU). However, the DLA can be configured with sufficient logic units to process the input data provided to an ANN and generate the output of the ANN according to a set of instructions generated for the DLA. Thus, the DLA can perform the computation of an ANN with little or no help from a CPU or another processor. Optionally, a conventional general purpose processor can also be configured as part of the DLA to perform operations that cannot be implemented efficiently using the vector/matrix processing units of the DLA, and/or that cannot be performed by the vector/matrix processing units of the DLA.

A typical ANN can be described/specified in a standard format (e.g., Open Neural Network Exchange (ONNX)). A compiler can be used to convert the description of the ANN into a set of instructions for the DLA to perform calculations of the ANN. The compiler can optimize the set of instructions to improve the performance of the DLA in implementing the ANN.

The DLA can have local storage, such as registers, buffers and/or caches, configured to store vector/matrix operands and the results of vector/matrix operations. Intermediate results in the registers can be pipelined/shifted in the DLA as operands for subsequent vector/matrix operations to reduce time and energy consumption in accessing memory/data and thus speed up typical patterns of vector/matrix operations in implementing a typical ANN. The capacity of registers, buffers and/or caches in the DLA is typically insufficient to hold the entire data set for implementing the computation of a typical ANN. Thus, a random access memory coupled to the DLA might be configured to provide an improved data storage capability for implementing a typical ANN. For example, the DLA might load data and instructions from the random access memory and store results back into the random access memory.

Various embodiments described herein seek to facilitate the performance of computations of Artificial Neural Networks (ANNs) within a NAND memory array. Such embodiments might be used as matrix-matrix units, matrix-vector units, and/or vector-vector units of a DLA.

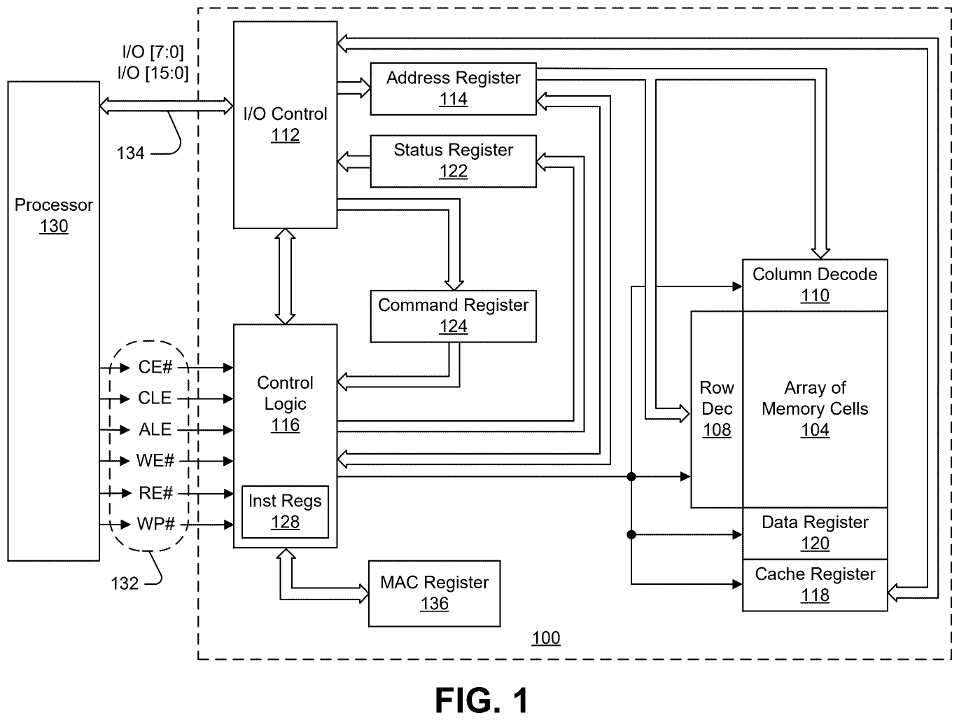

FIG. 1 is a simplified block diagram of a first apparatus, in the form of a memory (e.g., memory device) 100, in communication with a second apparatus, in the form of a processor 130, as part of a third apparatus, in the form of an electronic system, according to an embodiment. Some examples of electronic systems include personal computers, personal digital assistants (PDAs), digital cameras, digital media players, digital recorders, games, appliances, vehicles, wireless devices, mobile telephones and the like. The processor 130, e.g., a controller external to the memory device 100, might be a memory controller or other external host device.

Memory device 100 includes an array of memory cells 104 that might be logically arranged in rows and columns. The array of memory cells 104 might contain memory array structures in accordance with one or more embodiments. Memory cells of a logical row are typically connected to the same access line (commonly referred to as a word line) while memory cells of a logical column are typically selectively connected to the same data line (commonly referred to as a bit line). A single access line might be associated with more than one logical row of memory cells and a single data line might be associated with more than one logical column. Memory cells (not shown in FIG. 1) of at least a portion of array of memory cells 104 are capable of being programmed to one of at least two target data states.

A row decode circuitry 108 and a column decode circuitry 110 are provided to decode address signals. Address signals are received and decoded to access the array of memory cells 104. Memory device 100 also includes input/output (I/O) control circuitry 112 to manage input of commands, addresses and data to the memory device 100 as well as output of data and status information from the memory device 100. An address register 114 is in communication with I/O control circuitry 112 and row decode circuitry 108 and column decode circuitry 110 to latch the address signals prior to decoding. A command register 124 is in communication with I/O control circuitry 112 and control logic 116 to latch incoming commands.

A controller (e.g., the control logic 116 internal to the memory device 100) controls access to the array of memory cells 104 in response to the commands and might generate status information for the external processor 130, i.e., control logic 116 is configured to perform access operations (e.g., sensing operations [which might include read operations and verify operations], programming operations and/or erase operations) on the array of memory cells 104. The control logic 116 is in communication with row decode circuitry 108 and column decode circuitry 110 to control the row decode circuitry 108 and column decode circuitry 110 in response to the addresses. The control logic 116 might include instruction registers 128 which might represent computer-usable memory for storing computer-readable instructions. For some embodiments, the instruction registers 128 might represent firmware. Alternatively, the instruction registers 128 might represent a grouping of memory cells, e.g., reserved block(s) of memory cells, of the array of memory cells 104. The control logic 116 might be configured, e.g., in response to such computer-readable instructions, to cause the memory 100 to perform methods of one or more embodiments.

Control logic 116 might further be in communication with a cache register 118. Cache register 118 latches data, either incoming or outgoing, as directed by control logic 116 to temporarily store data while the array of memory cells 104 is busy writing or reading, respectively, other data. During a programming operation (e.g., write operation), data might be passed from the cache register 118 to the data register 120 for transfer to the array of memory cells 104; then new data might be latched in the cache register 118 from the I/O control circuitry 112. During a read operation, data might be passed from the cache register 118 to the I/O control circuitry 112 for output to the external processor 130; then new data might be passed from the data register 120 to the cache register 118. The cache register 118 and/or the data register 120 might form (e.g., might form a portion of) a page buffer of the memory device 100. A page buffer might further include sensing devices (not shown in FIG. 1) to sense a data state of a memory cell of the array of memory cells 104, e.g., by sensing a state of a data line connected to that memory cell. A status register 122 might be in communication with I/O control circuitry 112 and control logic 116 to latch the status information for output to the processor 130.

Control logic 116 might further be in communication with a Multiply-Accumulate (MAC) register 136. The MAC register 136 might represent a volatile memory, latches, or other storage location, e.g., volatile or non-volatile. For some embodiments, the MAC register 136 might represent a portion of the data register 120 and/or cache register 118. The MAC register 136 might further be in communication with one or more analog-to-digital converters as will be depicted in subsequent figures. The MAC register 136 might be configured to store partial products of one or more multiply operations for elements of vectors of a vector-vector operation, as well as respective sums of the multiply operations. The MAC register 136 might further be configured to store dot products of the vector-vector operations

Memory device 100 receives control signals at control logic 116 from processor 130 over a control link 132. The control signals might include a chip enable CE #, a command latch enable CLE, an address latch enable ALE, a write enable WE #, a read enable RE #, and a write protect WP #. Additional or alternative control signals (not shown) might be further received over control link 132 depending upon the nature of the memory device 100. Memory device 100 receives command signals (which represent commands), address signals (which represent addresses), and data signals (which represent data) from processor 130 over a multiplexed input/output (I/O) bus 134 and outputs data to processor 130 over I/O bus 134.

For example, the commands might be received over input/output (I/O) pins [7:0] of I/O bus 134 at I/O control circuitry 112 and might then be written into command register 124. The addresses might be received over input/output (I/O) pins [7:0] of I/O bus 134 at I/O control circuitry 112 and might then be written into address register 114. The data might be received over input/output (I/O) pins [7:0] for an 8-bit device or input/output (I/O) pins [15:0] for a 16-bit device at I/O control circuitry 112 and then might be written into cache register 118. The data might be subsequently written into data register 120 for programming the array of memory cells 104. For another embodiment, cache register 118 might be omitted, and the data might be written directly into data register 120. Data might also be output over input/output (I/O) pins [7:0] for an 8-bit device or input/output (I/O) pins [15:0] for a 16-bit device. Although reference might be made to I/O pins, they might include any conductive nodes providing for electrical connection to the memory device 100 by an external device (e.g., processor 130), such as conductive pads or conductive bumps as are commonly used.

It will be appreciated by those skilled in the art that additional circuitry and signals can be provided, and that the memory device 100 of FIG. 1 has been simplified. It should be recognized that the functionality of the various block components described with reference to FIG. 1 might not necessarily be segregated to distinct components or component portions of an integrated circuit device. For example, a single component or component portion of an integrated circuit device could be adapted to perform the functionality of more than one block component of FIG. 1. Alternatively, one or more components or component portions of an integrated circuit device could be combined to perform the functionality of a single block component of FIG. 1.

Additionally, while specific I/O pins are described in accordance with popular conventions for receipt and output of the various signals, it is noted that other combinations or numbers of I/O pins (or other I/O node structures) might be used in the various embodiments.

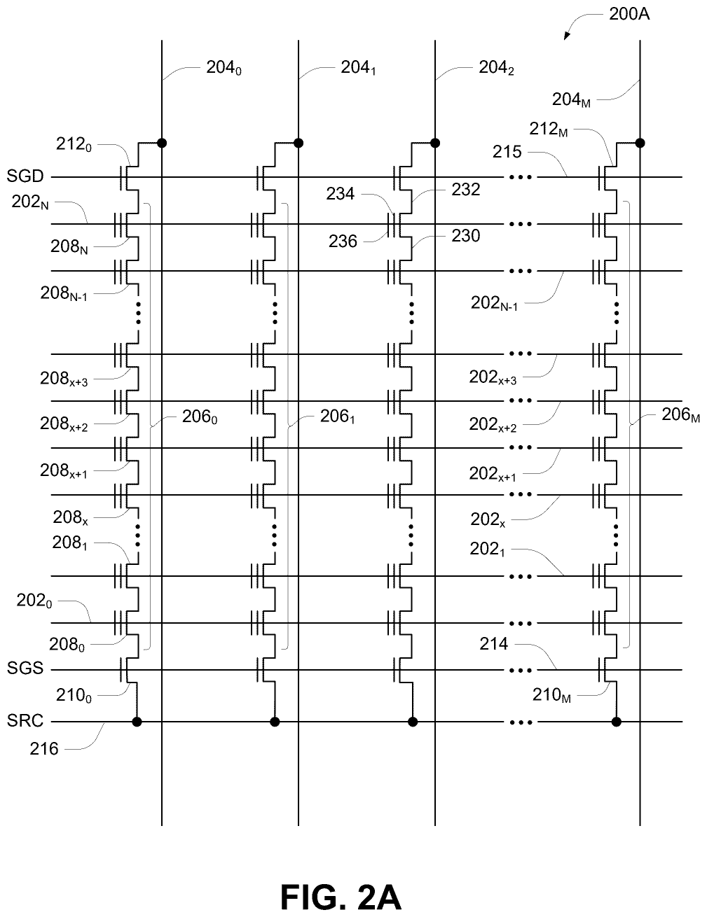

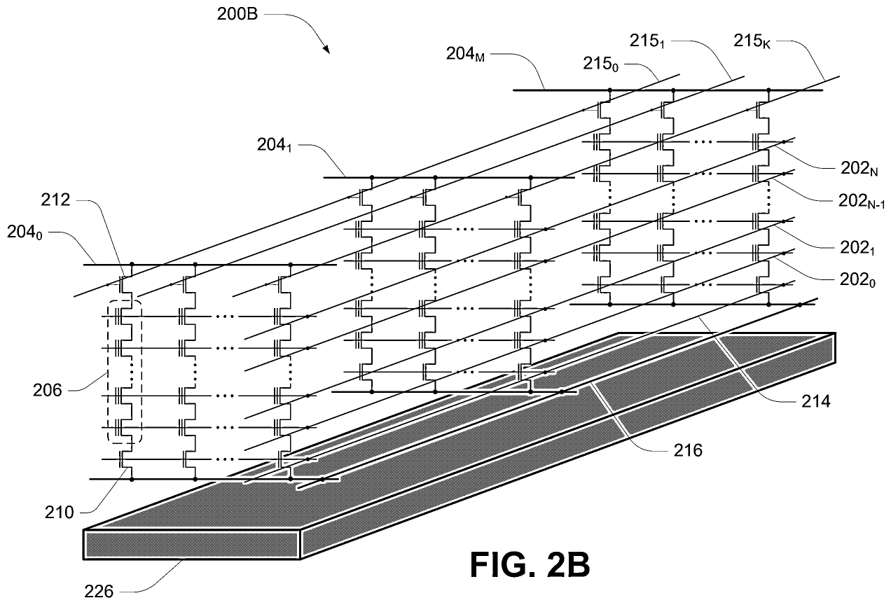

FIG. 2A is a schematic of a portion of an array of memory cells 200A, such as a NAND memory array, in accordance with an embodiment as could be used in a memory of the type described with reference to FIG. 1. The array of memory cells 200A includes access lines (e.g., word lines) 202₀ to 202_{N}, and a data line (e.g., bit line) 204. The array of memory cells 200A might be arranged in rows (each corresponding to an access line 202) and columns (each corresponding to a data line 204). Each column might include a string of series-connected memory cells (e.g., non-volatile memory cells), such as one of NAND strings 206₀ to 206_{M}. Each NAND string 206 might be connected (e.g., selectively connected) to a common source (SRC) 216 and might include memory cells 208₀ to 208_{N}. The memory cells 208 might represent non-volatile memory cells for storage of data.

The memory cells 208 of each NAND string 206 might be connected in series between a select gate 210 (e.g., a field-effect transistor), such as one of the select gates 210₀ to 210_{M}, and a select gate 212 (e.g., a field-effect transistor), such as one of the select gates 212₀ to 212_{M}. Select gates 210₀ to 210_{M} might be commonly connected to a select line 214, such as a source select line (SGS), and select gates 212₀ to 212_{M} might be connected to different select lines 215, e.g., select lines 215₀-215_{M}. A control gate of each select gate 210 might be connected to select line 214. A control gate of each select gate 212 might be connected to select line 215. As used herein, a field-effect transistor, e.g., an integrated circuit device using an electric field to control the flow of current, might be alternatively referred to simply as a transistor.

A source of each select gate 210 might be connected to common source (SRC) 216. The drain of each select gate 210 might be connected to a memory cell 208 of the corresponding NAND string 206. For example, the drain of select gate 210₀ might be connected to the source of memory cell 208₀ of the corresponding NAND string 206₀. Therefore, each select gate 210 for a corresponding NAND string 206 might be configured to selectively connect that NAND string 206 to common source 216.

The drain of each select gate 212 might be connected to the data line 204. The source of each select gate 212 might be connected to a memory cell 208 of the corresponding NAND string 206. For example, the source of select gate 212₀ might be connected to memory cell 208_{N} of the corresponding NAND string 206₀. Therefore, each select gate 212 for a corresponding NAND string 206 might be configured to selectively connect that NAND string 206 to the data line 204.

The access lines 202 and select lines 214 and 215 might be formed around channel material structures 244. Each channel material structure 244 might contain a channel material forming a channel of the select gate 210, the select gate 212, and each memory cell 208 of its respective NAND string 206. For example, the channel material structure 2440 might form a channel for the select gate 210₀, the select gate 212₀, and each memory cell 208₀-208_{N} of the NAND string 206₀.

Typical construction of memory cells 208 includes a data storage structure 234 (e.g., including a floating gate, charge trap, or other structure configured to store charge) that can determine a data state of the memory cell (e.g., through changes in threshold voltage), and a control gate 236, as shown in FIG. 2A. The data storage structure 234 might include conductive and/or dielectric structures while the control gate 236 is generally formed of one or more conductive materials. In some cases, memory cells 208 might further have a defined source/drain (e.g., source) 230 and a defined source/drain (e.g., drain) 232. Memory cells 208 have their control gates 236 connected to (and in some cases form) an access line 202.

A column of the memory cells 208 might be a NAND string 206 or a plurality of NAND strings 206 selectively connected to a given data line 204. A row of the memory cells 208 might be memory cells 208 commonly connected to a given access line 202. A row of memory cells 208 can, but need not, include all memory cells 208 commonly connected to a given access line 202. Rows of memory cells 208 might often be divided into one or more groups of physical pages of memory cells 208, and physical pages of memory cells 208 often include every other memory cell 208 commonly connected to a given access line 202. Other groupings of memory cells 208 commonly connected to a given access line 202 might also define a physical page of memory cells 208. For certain memory devices, all memory cells commonly connected to a given access line 202 might be deemed a physical page of memory cells. The portion of a physical page of memory cells (which, in some embodiments, could still be the entire row) that is read during a single read operation or programmed during a single programming operation (e.g., an upper or lower page of memory cells) might be deemed a logical page of memory cells. A block of memory cells might include memory cells that are configured to be erased together and that might share a common source 216. Unless expressly distinguished, any reference to a page of memory cells herein refers to the memory cells of a logical page of memory cells.

FIG. 2B is another schematic of a portion of an array of memory cells 200B as could be used in a memory of the type described with reference to FIG. 1, e.g., as a portion of array of memory cells 104. Like numbered elements in FIG. 2B correspond to the description as provided with respect to FIG. 2A. FIG. 2B provides additional detail of one example of a three-dimensional NAND memory array structure. The three-dimensional NAND memory array 200B might incorporate vertical structures which might include semiconductor pillars, which might be solid or hollow, where a portion of a pillar might act as a channel region of the memory cells of NAND strings 206, e.g., a region through which current might flow when a memory cell, e.g., a field-effect transistor, is activated. The NAND strings 206 might be each selectively connected to a data line 204₀-204_{M} by a select transistor 212 (e.g., that might be drain select transistors, commonly referred to as select gate drain) and to a common source 216 by a select transistor 210 (e.g., that might be source select transistors, commonly referred to as select gate source). Multiple NAND strings 206 might be selectively connected to the same data line 204. Subsets of NAND strings 206 can be connected to their respective data lines 204 by biasing the select lines 215₀-215_{K} to selectively activate particular select transistors 212 each between a NAND string 206 and a data line 204. The select transistors 210 can be activated by biasing the select line 214. Each access line 202 might be connected to multiple rows of memory cells of the memory array 200B. Rows of memory cells that are commonly connected to each other by a particular access line 202 might collectively be referred to as tiers.

The three-dimensional NAND memory array 200B might be formed over peripheral circuitry 226. The peripheral circuitry 226 might represent a variety of circuitry for accessing the memory array 200B. The peripheral circuitry 226 might include complementary circuit elements. For example, the peripheral circuitry 226 might include both n-channel region and p-channel region transistors formed overlying a same semiconductor substrate, a process commonly referred to as CMOS, or complementary metal-oxide-semiconductors. Although CMOS often no longer utilizes a strict metal-oxide-semiconductor construction due to advancements in integrated circuit fabrication and design, the CMOS designation remains as a matter of convenience.

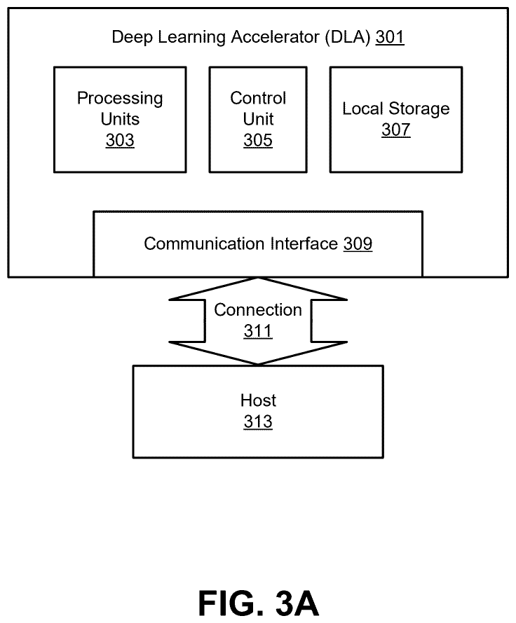

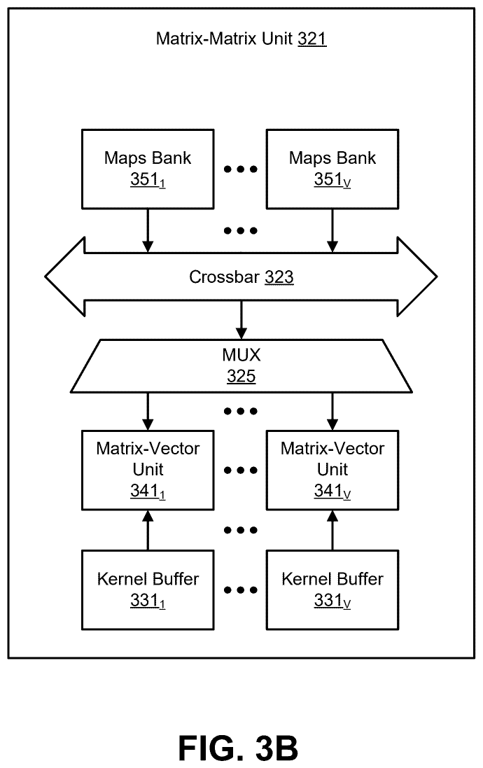

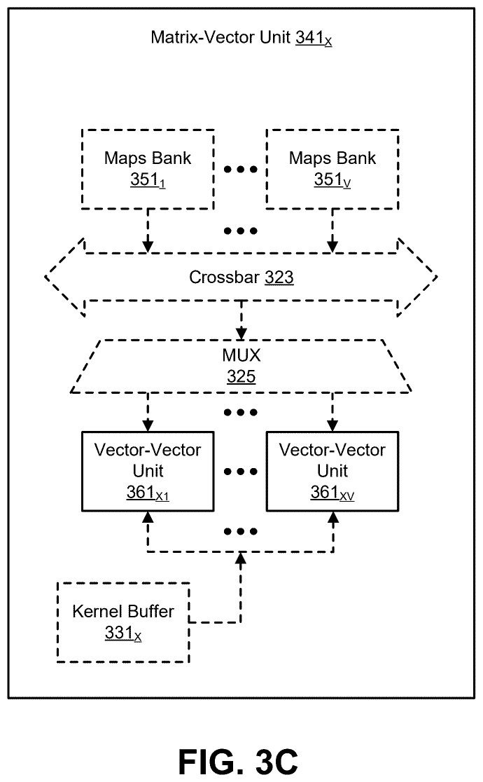

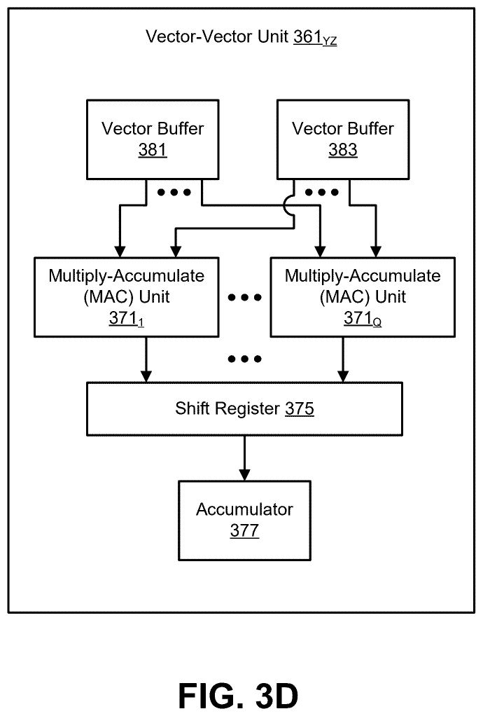

FIG. 3A shows a Deep Learning Accelerator 301 connected to a host 313. The Deep Learning Accelerator 301 might include processing units 303, a control unit 305, local storage 307, and a communication interface 309.

When vector and matrix operands (e.g., multiplicands and multipliers) are in the local storage 307, the control unit 305 can use the processing units 303 to perform vector and matrix operations in accordance with instructions. Further, the control unit 303 can load instructions and/or operands from the host 313 through a communication interface 311 and a connection (e.g., high speed/bandwidth connection) 319. The host 313 might be any device (e.g., controller, memory, application-specific integrated circuit (ASIC), or other integrated circuit device) capable of providing model data, instructions, and operands as input to the DLA 301, and capable of receiving output (e.g., results data) from the DLA 301.

The data access speed of the connection 311 might be configured based on the processing speed of the DLA 301. For example, after an amount of data and instructions have been loaded into the local storage 307, the control unit 305 can execute an instruction to operate on the data using the processing units 303 to generate output. Within the time period of processing to generate the output, the access bandwidth of the connection 311 might allow the same amount of data and instructions to be loaded into the local storage 307 for the next operation and the same amount of output to be stored back to the host 313. For example, while the control unit 303 is using a portion of the local storage 307 to process data and generate output, the communication interface 309 can offload the output of a prior operation into the host 313 from, and load operand data and instructions into, another portion of the local storage 307. Thus, the utilization and performance of the DLA 301 are not restricted or reduced by the bandwidth of the connection 311.

The host 313 might be used to store the model data of an ANN and to buffer input data for the ANN. The model data generally would not change frequently. The model data can include the output generated by a compiler for the DLA to implement the ANN. The model data typically includes matrices used in the description of the ANN and instructions generated for the DLA 301 to perform vector/matrix operations of the ANN based on vector/matrix operations of the granularity of the DLA 301. The instructions operate not only on the vector/matrix operations of the ANN, but also on the input data for the ANN.

The processing units 303 of the DLA 301 can include vector-vector units, matrix-vector units, and/or matrix-matrix units. Examples of units configured to perform for vector-vector operations, matrix-vector operations, and matrix-matrix operations are discussed below in connection with FIGS. 3B-3D.

FIG. 3B shows a processing unit as a matrix-matrix unit 321 configured to perform matrix-matrix operations. For example, the matrix-matrix unit 321 of FIG. 3B can be used as one of the processing units 303 of the DLA 301 of FIG. 3A.

In FIG. 3B, the matrix-matrix unit 321 includes multiple kernel buffers 331₁ to 331_{V} and multiple the maps banks 351₁ to 351_{V}. The integer value of V might be equal to a size (e.g., a maximum size) of a matrix to be operated upon by the DLA 301. For example, V might represent a number of rows and a number of columns of a matrix.

Each of the maps banks 351₁ to 351_{V} might store one vector of a matrix operand (e.g., a row of a matrix multiplicand) that has multiple vectors stored in the maps banks 351₁ to 351_{V}, respectively; and each of the kernel buffers 331₁ to 331v might store one vector of another matrix operand (e.g., a column of a matrix multiplier) that has multiple vectors stored in the kernel buffers 331₁ to 331_{V}, respectively. The matrix-matrix unit 321 might be configured to perform multiplication and accumulation operations on the elements of the two matrix operands, using multiple matrix-vector units 341₁ to 341_{V} that might operate in parallel.

A crossbar 323 might connect the maps banks 351₁ to 351_{V} to the matrix-vector units 341₁ to 341_{V} through a multiplexer (MUX) 325. The same matrix operand stored in the maps bank 351₁ to 351_{V} might be provided via the crossbar 323 to each of the matrix-vector units 341₁ to 341_{V}, and the matrix-vector units 341₁ to 341_{V} might receive data elements from the maps banks 351₁ to 351_{V} in parallel. Each of the kernel buffers 331₁ to 331_{V} might be connected to a respective one in the matrix-vector units 341₁ to 341_{V} and might provide a vector operand to its respective matrix-vector unit 341. The matrix-vector units 341₁ to 341_{V} might operate concurrently to compute the operation of the same matrix operand, stored in the maps banks 351₁ to 351_{V} multiplied by the corresponding vectors stored in the kernel buffers 331₁ to 331_{V}.

Each of the matrix-vector units 341₁ to 341_{V} in FIG. 3B might be implemented in a way as illustrated in FIG. 3C. FIG. 3C shows a processing unit as a matrix-vector unit 341_{X} configured to perform matrix-vector operations, where X is any integer value from 1 to V. For example, the matrix-vector unit 341_{X} of FIG. 3C might represent any of the matrix-vector units 341 in the matrix-matrix unit 321 of FIG. 3B.

In FIG. 3C, each of the maps banks 351₁ to 351_{V} stores one vector of a matrix operand that has multiple vectors stored in the maps banks 351₁ to 351_{V} respectively, in a way similar to the maps banks 351₁ to 351_{V} of FIG. 3B. The crossbar 323 in FIG. 3C provides the vectors from the maps banks 351₁ to 351V to the vector-vector units 361_{X1} to 361_{XV}, respectively. A same vector stored in the kernel buffer 331_{X} is provided to the vector-vector units 361₁ to 361_{V}.

The vector-vector units 361₁ to 361_{V} might operate concurrently to compute the operation of the corresponding vector operands, stored in the maps banks 351₁ to 351_{V}, respectively, multiplied by the same vector operand that is stored in the kernel buffer 331_{X}.

Each of the vector-vector units 361₁ to 361_{V} in FIG. 3C might be implemented in a way as illustrated in FIG. 3D. FIG. 3D shows a processing unit as a vector-vector unit 361_{YZ} configured to perform vector-vector operations, where Y and Z are independently any integer value from 1 to V. For example, the vector-vector unit 361_{YZ} of FIG. 3D might be used as any of the vector-vector units 361_{X1} to 361_{XV} in the matrix-vector unit 341_{X} of FIG. 3C.

In FIG. 3D, the vector-vector unit 361_{YZ} has multiple multiply-accumulate (MAC) units 371₁ to 371_{Q}, where Q might be an integer value less than or equal to a number of digits (e.g., maximum number of digits) of the elements of the vectors to be operated upon. Each of the MAC units 371₁ to 371_{Q} can receive two numbers (e.g., vector elements) as operands, perform multiplication of the two numbers, and add the result of the multiplication to a sum maintained in the MAC unit.

Each of the vector buffers 381 and 383 might store a respective vector as a list of numbers. A pair of numbers, each from one of the vector buffers 381 and 383, can be provided to each of the MAC units 371₁ to 371_{Q} as input. The MAC units 371₁ to 371_{Q} can receive multiple pairs of numbers from the vector buffers 381 and 383 in parallel and perform the multiply-accumulate (MAC) operations in parallel. The outputs from the MAC units 371₁ to 371_{Q} might be stored into the shift register 375, and an accumulator 377 might compute the sum of the results in the shift register 375.

When the vector-vector unit 361_{YZ} of FIG. 3D is implemented in a matrix-vector unit 341_{X} of FIG. 3C, the vector-vector unit 361_{YZ} might use a respective maps bank 351 (e.g., maps bank 351_{Z}) as the vector buffer 381, and a respective kernel buffer 331 (e.g., kernel buffer 331_{Y}) of the matrix-vector unit 341_{X} as the vector buffer 383.

The vector buffers 381 and 383 might have a same length to store the same number/count of data elements. The length can be equal to, or a multiple of, the count of MAC units 371₁ to 371_{Q} in the vector-vector unit 361_{YZ}. When the length of the vector buffers 381 and 383 is a multiple of the count of MAC units 371₁ to 371_{Q}, a number of pairs of inputs, equal to the count of the MAC units 371₁ to 371_{Q}, can be provided from the vector buffers 381 and 383 as inputs to the MAC units 371₁ to 371_{Q} in each iteration; and the vector buffers 381 and 383 can feed their elements into the MAC units 371₁ to 371_{Q} through multiple iterations.

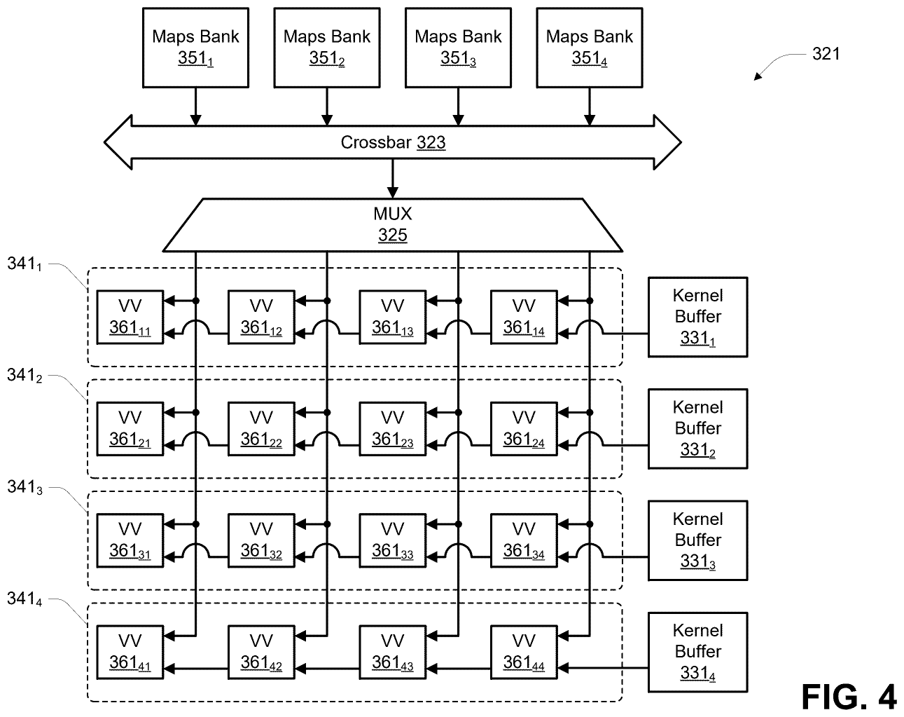

FIG. 4 depicts a matrix-matrix unit 321 having four matrix-vector units 341 (e.g., 341₁-341₄) which each contain a corresponding four vector-vector units 361 (e.g., 361₁₁-361₁₄, 361₂₁-361₂₄, 361₃₁-361₃₄, or 361₄₁-361₄₄, respectively). Rows (e.g., vectors) of a multiplicand matrix might be provided to respective vector-vector units 361 from the maps banks 351 (e.g., 351₁-351₄) through the crossbar 323 and multiplexer 325 for each matrix-vector unit 341. Columns (e.g., vectors) of a multiplier matrix might be provided to respective vector-vector units 361 from the kernel buffers 331 (e.g., 331₁-331₄). The columns (e.g., vectors) of the multiplier matrix might represent pixel data of an image, while the rows (e.g., vectors) of the multiplicand matrix might represent filters for image recognition (e.g., for recognition of a straight line or horizontal line).

The matrix-matrix unit 321 might be configured to compute a dot product of the multiplicand matrix and the multiplier matrix, which might be of equal dimensions. The vector-vector units 361 of the matrix-matrix unit 321 might be configured to compute a dot product of two vectors of the two matrices, e.g., a row of the multiplicand matrix and a column of the multiplier matrix, and thus represent a respective element of a results matrix. The collective results of the vector-vector units 361 for each matrix-vector unit 341 might represent a respective row of the results matrix, while the collective results of the vector-vector units 361 for all of the matrix-vector units 341 of the matrix-matrix unit 321 might represent the results matrix.

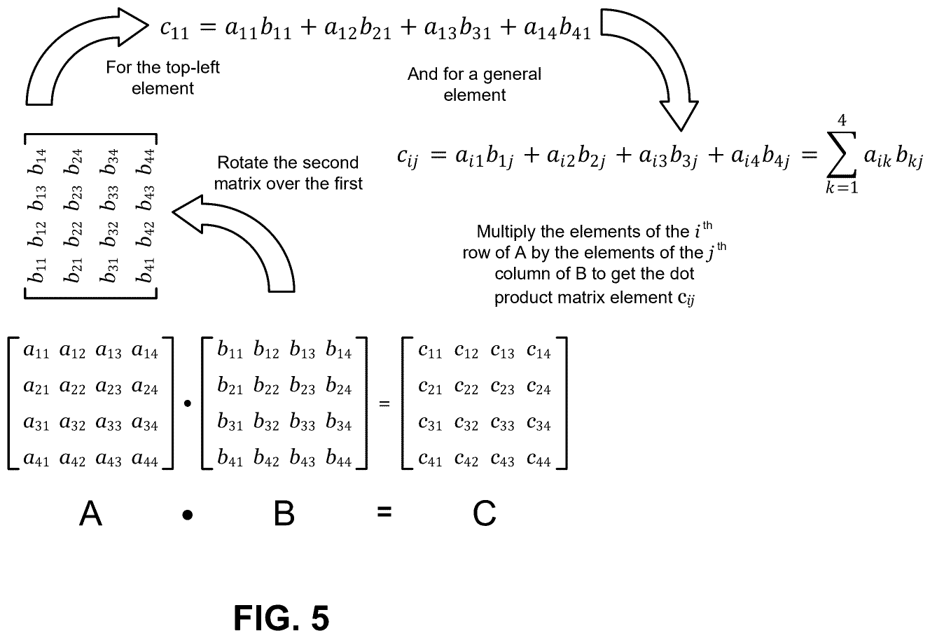

FIG. 5 details the computations of the matrix-matrix unit 321 of FIG. 4. Consider the example of the matrix A as a multiplicand and the matrix B as a multiplier. The dot product of these two matrices A and B to produce the results matrix C would include the dot product of the first row of the matrix A (e.g., a₁₁, a₁₂, a₁₃, and a₁₄) and the first column of the matrix B (e.g., b₁₁, b₂₁, b₃₁, and b₄₁) to yield the element of the matrix C of its first row and first column (e.g., c₁₁) according to Equation 1:

$${c}_{11} = {a}_{11} {b}_{11} + {a}_{12} {b}_{21} + {a}_{13} {b}_{31} + {a}_{14} {b}_{41} \qquad Eq . 1$$

Remaining elements of the matrix C might be similarly determined for the various rows of the matrix A and the various columns of the matrix B in a similar matter. For example, first each value of i from 1 to 4, and each value of j from 1 to 4 for the matrices depicted in FIG. 5, the element cᵢⱼ of the matrix C can be determined from the general Equation 2:

$${c}_{i j} = {a}_{i 1} {b}_{1 j} + {a}_{i 2} {b}_{2 j} + {a}_{i 3} {b}_{3 j} + {a}_{i 4} {b}_{4 j} = {\sum }_{k = 1}^{4} {a}_{ik} \cdot {b}_{kj} \qquad Eq . 2$$

Each element of the multiplicand matrix A, the multiplier matrix B, and the results matrix C might represent a number, which might be binary or otherwise. As such, each element of the results matrix C might represent a summation or accumulation of the products of corresponding elements of a row from the multiplicand matrix A and a column of the multiplier matrix B. Each matrix-vector unit 341, through its corresponding vector-vector units 361, might compute a vector (e.g., a row) of the results matrix C, while the matrix-matrix unit 321, through its corresponding matrix-vector units 341, might compute the entirety of the results matrix C.

These computations performed by the vector-vector units 361, the matrix-vector units 341, and the matrix-matrix units 321 can be replicated within a NAND memory. Specifically, an array of series-connected (e.g., NAND) memory cells can be configured to generate values representative of dot products of respective vectors from two matrices, e.g., a multiplicand matrix and a multiplier matrix.

For example, to multiply two numbers within a NAND memory, a set of memory cells commonly connected to a same access line, or collectively connected to a set of access lines, could be programmed to have threshold voltages indicative of one number, e.g., the multiplicand, while voltages could be applied to the data lines selectively connected to the set of memory cells that are indicative of individual digits (e.g., bits) of the other number, e.g., the multipliers. Note that the multiplicand might utilize either binary encoding or thermometric encoding for storage of its data, e.g., the value of 12 base 10 might be binary encoded as 1100, or thermometric encoded as 111111111111. While thermometric encoding might utilize more memory cells for storage, it might also afford higher accuracy than binary encoding.

Subsets of the set of memory cells might be programmed to represent a respective digit (binary or thermometric) of the multiplicand, e.g., by collectively presenting a respective resistance value between their respective data lines and the common source in response to a same control signal or set of control signals applied to their control gates. Each subset of memory cells might contain one or more memory cells (which could include all memory cells) of a single string of series-connected memory cells, or of multiple strings of series-connected memory cells. As will be described in more detail, a subset of memory cells corresponding to one digit of the multiplicand might contain a same number of memory cells and/or a same arrangement of memory cells as the subsets of memory cells for each remaining digit of the multiplicand. Alternatively, a subset of memory cells corresponding to one digit of the multiplicand might contain a different number of memory cells and/or a different arrangement of memory cells than a respective subset of memory cells for one or more remaining digits of the multiplicand. The set of memory cells might be programmed in a binary fashion, e.g., each memory cell either activated (e.g., to represent a first logic level) or deactivated (e.g., to represent a second logic level different than the first logic level) in response to its respective control signal, or in an analog fashion, e.g., different memory cells exhibiting different levels of resistance (e.g., R, R/2, R/4, R/8, etc.) in response to a same control signal.

Respective digits of the multiplier might be applied to the respective data lines of the set of memory cells sequentially while the set of memory cells receives its control signal or set of control signals. In this manner, the collective current flow through the set of memory cells from its respective data lines to the common source might be indicative of the value of the multiplicand multiplied by one digit of the multiplier. This current could be converted to a digital (e.g., binary) value using an analog-to-digital converter (ADC) in a manner well understood in the art of integrated circuit design. The voltage levels corresponding to the digits of the multiplier might be applied in a binary fashion, e.g., applying a first voltage level to generate a first voltage differential between each data line and the common source (e.g., to represent a first logic level) and applying a second voltage level to generate a second voltage differential lower than the first voltage differential (e.g., a de minimis voltage differential) between each data line and the common source (e.g., to represent a second logic level different than the first logic level).

Alternatively, the voltage levels corresponding to the digits of the multiplier might be applied in an analog fashion. For example, to represent the first logic level (e.g., “1”) for a least significant digit (e.g., least significant bit or LSB), a first voltage level might be applied to its respective data line(s) to generate a first voltage differential between the respective data line(s) and the common source, to represent the first logic level for a next significant digit (e.g., a second digit), a second voltage level higher than the first voltage level (e.g., two times the first voltage level) might be applied to its respective data line(s) to generate a second voltage differential (e.g., two times the first voltage differential) between the respective data line(s) and the common source, to represent the first logic level for a next significant digit (e.g., a third digit), a third voltage level higher than the second voltage level (e.g., two times the second voltage level) might be applied to its respective data line(s) to generate a third voltage differential (e.g., two times the second voltage differential) between the respective data line(s) and the common source, and so on. Similarly, to represent the second logic level (e.g., “0”) for any digit, a voltage level might be applied to the data lines to generate a voltage differential lower than any voltage differential generated for the first logic level (e.g., a de minimis voltage differential and/or a voltage differential having an opposite polarity) between each data line and the common source.

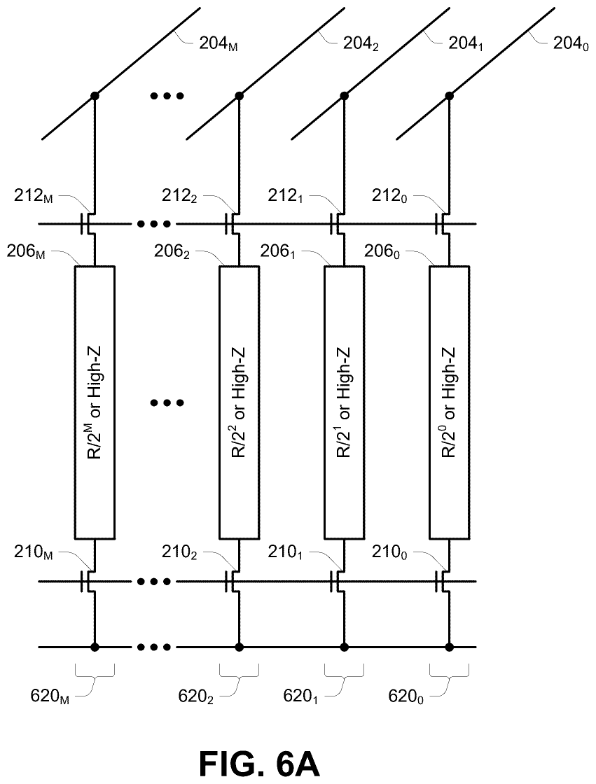

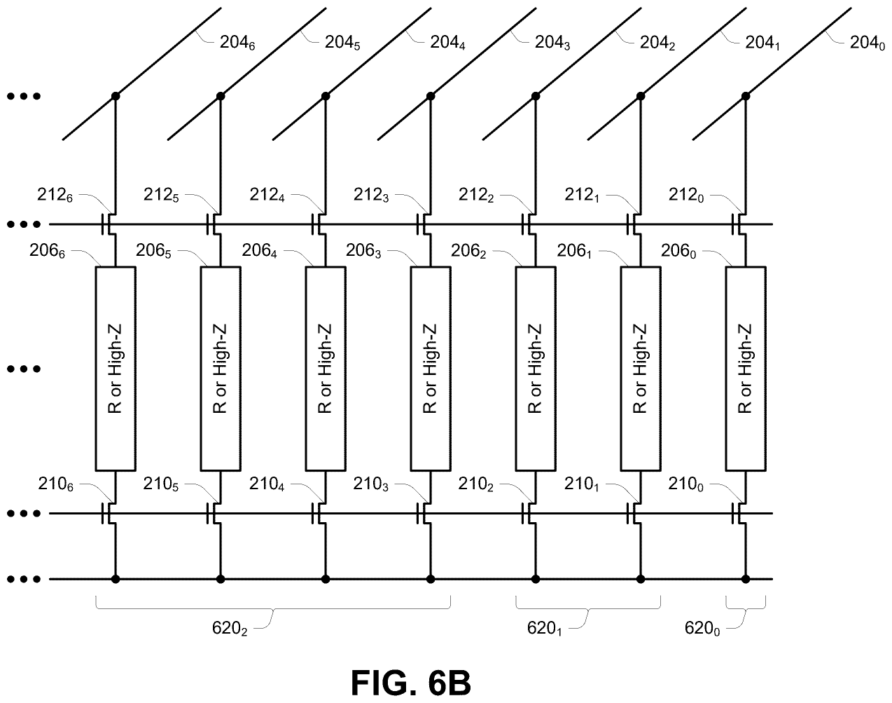

FIGS. 6A and 6B depict portions of an array of memory cells configured to store digits of a multiplicand in an analog fashion and a binary fashion, respectively. Like numbered elements in FIG. 2B correspond to the description as provided with respect to FIG. 2A. Note that the access lines 202 are not depicted in FIGS. 6A-6B for clarity.

In FIG. 6A, the subset of memory cells corresponding to a first digit 620₀ of the multiplicand, e.g., a least significant digit, might include one or more (e.g., which might include all memory cells) memory cells of the string of series-connected memory cells 206₀ that are configured either to exhibit a resistance value of R/2° or R to represent a first logic level (e.g., “1”) for the digit 620₀, or to exhibit a high impedance (High-Z) to represent a second logic level (e.g., “0”) different than the first logic level for the digit 620₀ in response to a set of control signals applied to the access lines 202 (not depicted in FIG. 6A) for the strings of series-connected memory cells 206. The subset of memory cells corresponding to a next digit 620₁ of the multiplicand might include one or more memory cells (e.g., which might include all memory cells) of the string of series-connected memory cells 206₁ that are configured either to exhibit a resistance value of R/2¹ or R/2 to represent the first logic level for the digit 620₁, or to exhibit a high impedance to represent the second logic level for the digit 620₁ in response to the set of control signals applied to the access lines 202 (not depicted in FIG. 6A) for the strings of series-connected memory cells 206. The subset of memory cells corresponding to a next digit 620₂ of the multiplicand might include one or more memory cells (e.g., which might include all memory cells) of the string of series-connected memory cells 206₂ that are configured either to exhibit a resistance value of R/2² or R/4 to represent the first logic level for the digit 620₂, or to exhibit a high impedance to represent the second logic level for the digit 620₂ in response to the set of control signals applied to the access lines 202 (not depicted in FIG. 6A) for the strings of series-connected memory cells 206. This might continue in like fashion for each additional digit 620 of the multiplicand up to a last digit 620_{M} of the multiplicand, e.g., a most significant digit, such that the subset of memory cells corresponding to the last digit 620 of the multiplicand might include one or more memory cells (e.g., which might include all memory cells) of the string of series-connected memory cells 206_{M} that are configured either to exhibit a resistance value of R/2^{M} to represent the first logic level for the digit 620_{M}, or to exhibit a high impedance to represent the second logic level for the digit 620_{M} in response to the set of control signals applied to the access lines 202 (not depicted in FIG. 6A) for the strings of series-connected memory cells 206. In this manner, each string of series-connected memory cells 206 might correspond to a respective digit (e.g., a single respective digit) of the multiplicand, and each digit of the multiplicand might correspond to one or more strings of series-connected memory cells 206.

Note that although FIG. 6A depicts a single string of series-connected memory cells 206 as corresponding to each digit 620 of the multiplicand, each digit 620 of the multiplicand might correspond to one or more strings of series-connected memory cells 206. For example, the subset of memory cells corresponding to the first digit 620₀ of the multiplicand might include one or more memory cells of two strings of series-connected memory cells 206 that are each configured either to exhibit a resistance value of R to represent the first logic level for the digit 620₀ or to exhibit a high impedance to represent the second logic level for the digit 620₀, the subset of memory cells corresponding to the second digit 620₁ of the multiplicand might include one or more memory cells of two strings of series-connected memory cells 206 that are each configured either to exhibit a resistance value of R/2 to represent the first logic level for the digit 620₁ or to exhibit a high impedance to represent the second logic level for the digit 620₁, the subset of memory cells corresponding to the third digit 620₂ of the multiplicand might include one or more memory cells of two strings of series-connected memory cells 206 that are each configured either to exhibit a resistance value of R/4 to represent the first logic level for the digit 620₂ or to exhibit a high impedance to represent the second logic level for the digit 620₂, and so on. In addition, although the strings of series-connected memory cells 206 corresponding to each digit 620 of the multiplicand are depicted to be immediately adjacent one another, the strings of series-connected memory cells 206 corresponding to the digits 620 of the multiplicand might be interleaved with strings of series-connected memory cells 206 not corresponding to the digits 620 of the multiplicand, e.g., every other string of series-connected memory cells 206 or some other mixture of strings of series-connected memory cells 206 corresponding to the digits 620 of the multiplicand and strings of series-connected memory cells 206 not corresponding to the digits 620 of the multiplicand. Furthermore, while depicted to be arranged in an order from least significant digit 620₀ to most significant digit 620_{M}, their order could be altered or even randomized as this would not be expected to alter their collective conductance in any significant manner.

In FIG. 6B, the subset of memory cells corresponding to a first digit 620₀ of the multiplicand, e.g., a least significant digit, might include one or more memory cells (e.g., which might include all memory cells) of the string of series-connected memory cells 206₀ that are configured either to exhibit a resistance value of R to represent a first logic level (e.g., “1”) for the digit 620₀, or to exhibit a high impedance to represent a second logic level (e.g., “0”) different than the first logic level for the digit 620₀ in response to a set of control signals applied to the access lines 202 (not depicted in FIG. 6B) for the strings of series-connected memory cells 206. The subset of memory cells corresponding to a next digit 620₁ of the multiplicand might include one or more memory cells (e.g., which might include all memory cells) of the strings of series-connected memory cells 206₁ and 206₂ that are configured either to exhibit a resistance value of R for each string of series-connected memory cells 206 to represent the first logic level for the digit 620₁, or to exhibit a high impedance for each string of series-connected memory cells 206 to represent the second logic level for the digit 620₁ in response to the set of control signals applied to the access lines 202 (not depicted in FIG. 6BA) for the strings of series-connected memory cells 206. The subset of memory cells corresponding to a next digit 620₂ of the multiplicand might include one or more memory cells (e.g., which might include all memory cells) of the strings of series-connected memory cells 206₃ through 206₆ that are configured either to exhibit a resistance value of R for each string of series-connected memory cells 206 to represent the first logic level for the digit 620₂, or to exhibit a high impedance for each string of series-connected memory cells 206 to represent the second logic level for the digit 620₂ in response to the set of control signals applied to the access lines 202 (not depicted in FIG. 6B) for the strings of series-connected memory cells 206. This might continue in like fashion for each additional digit 620 of the multiplicand up to a last digit of the multiplicand, e.g., a most significant digit, such that the subset of memory cells corresponding to each digit of the multiplicand might include one or more memory cells (e.g., which might include all memory cells) of a number of strings of series-connected memory cells 206 that might be two times the number of strings of series-connected memory cells 206 corresponding to a previous digit of the multiplicand, where each string of series-connected memory cells 206 corresponding to that digit of the multiplicand is configured either to exhibit a resistance value of R to represent the first logic level for that digit 620, or to exhibit a high impedance to represent the second logic level for that digit 620 in response to the set of control signals applied to the access lines 202 (not depicted in FIG. 6B) for the strings of series-connected memory cells 206.

As with the example of FIG. 6A, the first digit of the multiplicand 620₀ might correspond to more than one string of series-connected memory cells 206, with like adjustments to the number of strings of series-connected memory cells 206 for each remaining digit of the multiplicand. In addition, strings of series-connected memory cells 206 corresponding to the digits 620 of the multiplicand might be interleaved with strings of series-connected memory cells 206 not corresponding to the digits 620 of the multiplicand, and/or might be rearranged. Furthermore, FIG. 6B also might be used to describe thermometric encoding. For example, a set of memory cells being programmed to represent a number in thermometric encoding might include one or more memory cells (e.g., which might include all memory cells) of a number of strings of series-connected memory cells 206 that is a multiple (e.g., 1, 2, 3, etc.) of the number to be represented, e.g., to represent 3 base 10, the set of memory cells might include one or more memory cells of each of three strings of series-connected memory cells 206, e.g., strings of series-connected memory cells 206₀-206₂, each configured to exhibit a resistance value of R, with remaining strings of series-connected memory cells 206 corresponding to the multiplicand might be configured to exhibit a high impedance.

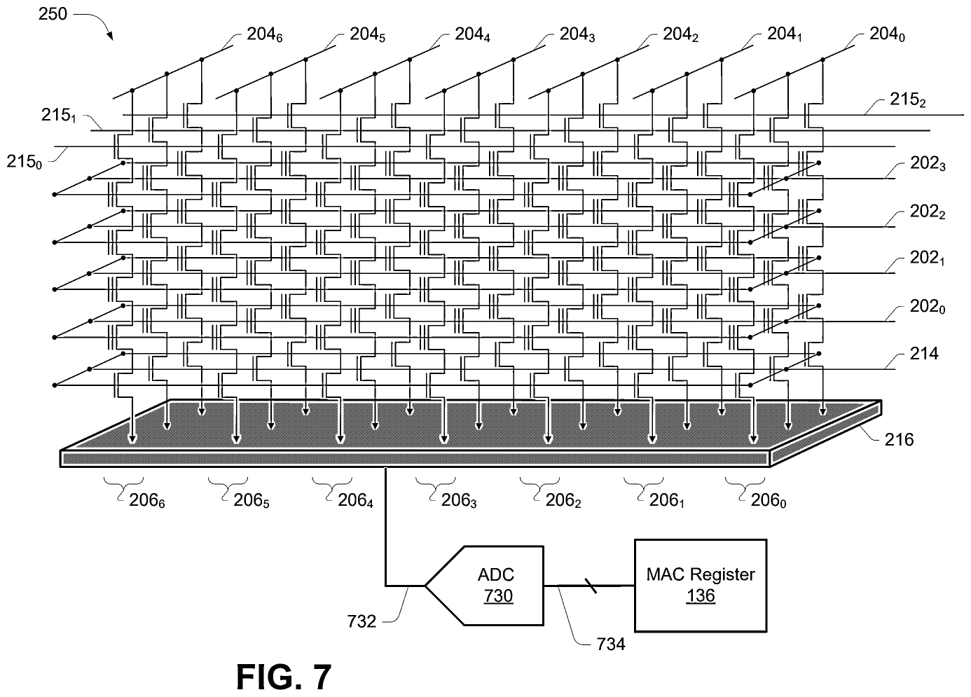

FIG. 7 depicts a portion of an array of memory cells (e.g., a block of memory cells 250) for use in discussing arithmetic operations in accordance with embodiments. FIG. 7 depicts seven strings of series-connected memory cells (e.g., 206₀-206₆) including memory cells (not labeled in FIG. 7) selectively connected to data lines 204₀-204₆ through select gates (not labeled in FIG. 7) responsive to a control signal applied to select line 215₀ and selectively connected to a common source 216 through select gates (not labeled in FIG. 7) responsive to a control signal applied to select line 214, seven strings of series-connected memory cells (not labeled in FIG. 7) including memory cells (not labeled in FIG. 7) selectively connected to data lines 204₀-204₆ through select gates (not labeled in FIG. 7) responsive to a control signal applied to select line 2151 and selectively connected to the common source 216 through select gates (not labeled in FIG. 7) responsive to a control signal applied to select line 214, and seven strings of series-connected memory cells (not labeled in FIG. 7) including memory cells (not labeled in FIG. 7) selectively connected to data lines 204₀-204₆ through select gates (not labeled in FIG. 7) responsive to a control signal applied to select line 2152 and selectively connected to the common source 216 through select gates (not labeled in FIG. 7) responsive to a control signal applied to select line 214.

The common source 216 might be connected to an input 732 of an analog-to-digital converter (ADC) 730. An output 734 of the ADC 730 might include a number of signal lines, each configured to provide a respective digital signal having one of two logic levels, e.g., either a “1” or a “0” logic level. The ADC 730 might be configured to receive an analog signal (e.g., an electric current) from the common source 216 at its input 732, and to generate a set of digital signals at its output 734 representative of a magnitude of the electric current received at its input 732. Consider the example of the ADC 730 being configured to accept current levels from A_{low} to A_{high}, where A_{low} might be zero current flow or some positive value, and A_{high} might be a current level higher than any expected current level to be received by the ADC 730. The ADC 730 might further be configured to output D digits of output data to its output 734. In this example, the resolution Q might be equal to (A_{high}−A_{low})/2\hat{ }D. Continuing with this example, if D=8, current levels received at the input 732 of the ADC 730 that are greater than or equal to A_{low} and less than A_{low}+Q might result in a generated set of digital signals at the output 734 of 00000000, current levels received at the input 732 of the ADC 730 that are greater than or equal to A_{low}+Q and less than A_{low}+2*Q might result in a generated set of digital signals at the output 734 of 00000001, current levels received at the input 732 of the ADC 730 that are greater than or equal to A_{low}+2*Q and less than A_{low}+3*Q might result in a generated set of digital signals at the output 734 of 00000010, current levels received at the input 732 of the ADC 730 that are greater than or equal to A_{low}+3*Q and less than A_{low}+4*Q might result in a generated set of digital signals at the output 734 of 00000011, and so on, until current levels received at the input 732 of the ADC 730 that are greater than or equal to A_{low}+255*Q might result in a generated set of digital signals at the output 734 of 11111111. While this example might represent a relationship approaching a linear function, the function need not be linear in order to generate a digital value representative of a received current level.

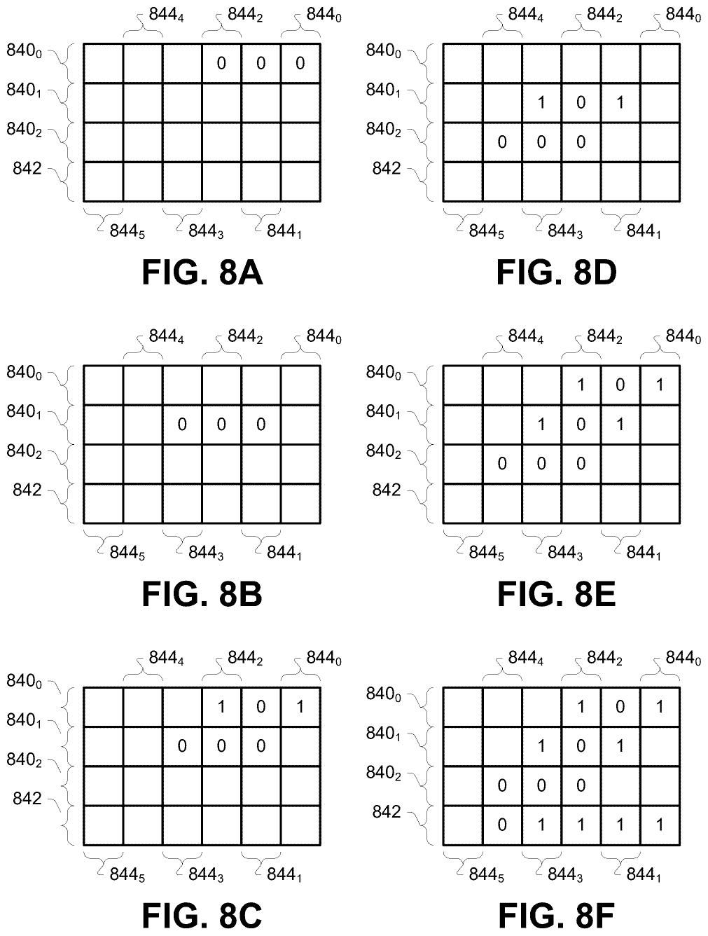

FIGS. 8A-8F depict registers during a multiply-accumulate operation in accordance with an embodiment. FIGS. 8A-8F will be described with reference to FIG. 7. The example of FIGS. 8A-8F might store the multiplicand in either an analog fashion (e.g., as discussed with reference to FIG. 6A), or a binary fashion (e.g., as discussed with reference to FIG. 6B). Voltages indicative of digits of the multiplier might be applied in a binary fashion, e.g., either a voltage indicative of a digit having a logical value of 1 or a voltage indicative of a digit having a logical value of 0.

The discussion of carrying out the multiply-accumulate operation will presume an example of storing the multiplicand to memory cells 208 of the strings of series-connected memory cells 206₀-206₆ of FIG. 7 corresponding to the access line 202₃ (e.g., having their control gates connected to the access line 202₃) and to the drain select line 215₀ (e.g., being selectively connected to a respective data line 204 through a drain select gate 212 having its control gate connected to the drain select line 215₀). To simplify the example, the ADC 730 will be described as a three-digit ADC, e.g., having eight possible digital outputs. In practice, the ADC 730 might be expected to have higher order outputs (e.g., eight-digit, sixteen-digit, or more), and thus much higher granularity. Table 1 depicts one possible relationship between the digital value of the output of the example ADC 730 for various levels of current flow A₁ to A₇ from the common source 216, where A₁<A₂<A₃<A₄<A₅<A₆<A₇. Note that absolute values of the current levels A₁-A₇ would generally depend on the selected design parameters, e.g., a number of digits of output from the ADC 730, voltages selected for driving access lines 202 and data lines 204, a maximum expected number of NAND strings 206 that might be conducting, etc.

TABLE 1
Digital Value vs Current Flow in Three-Digit ADC

| Amps | | |
|---|---|---|
| Greater Than or Equal To | Less Than | Digital Value |
| | A₁ | 000 |
| A₁ | A₂ | 001 |
| A₂ | A₃ | 010 |
| A₃ | A₄ | 011 |
| A₄ | A₅ | 100 |
| A₅ | A₆ | 101 |
| A₆ | A₇ | 110 |
| A₇ | | 111 |

For the example of FIGS. 8A-8F the multiplicand might be the digital value 101, while the multiplier might be the digital value 011. To store the multiplicand 101 to the strings of series-connected memory cells 206₀-206₆ in an analog fashion using binary encoding, threshold voltages of the memory cells of the strings of series-connected memory cells 206₀-206₆ might be programmed such that a first grouping of strings of series-connected memory cells 206 (e.g., string of series-connected memory cells 206₀) of the strings of series-connected memory cells 206₀-206₆ might exhibit a resistance representative of a resistance value R (e.g., R/2⁰) in response to a set of control signals applied to the access lines 202₀-202₃, a second grouping of strings of series-connected memory cells 206 (e.g., string of series-connected memory cells 206₁) of the strings of series-connected memory cells 206₀-206₆ might exhibit a high impedance in response to the set of control signals applied to the access lines 202₀-202₃, a third grouping of strings of series-connected memory cells 206 (e.g., string of series-connected memory cells 206₂) of the strings of series-connected memory cells 206₀-206₆ might exhibit a resistance representative of a resistance value of R/4 (e.g., R/2²) in response to the set of control signals applied to the access lines 202₀-202₃, and a fourth grouping of strings of series-connected memory cells 206 (e.g., strings of series-connected memory cells 206₃-206₆) of the strings of series-connected memory cells 206₀-206₆ might exhibit a high impedance in response to the set of control signals applied to the access lines 202₀-202₃. In this manner, in response to the set of control signals applied to the access lines 202₀-202₃, the strings of series-connected memory cells 206₀-206₆ might collectively exhibit a resistance value approaching R/5 representative of the digital value 101.

Alternatively, consider the example where the multiplicand is stored in a binary fashion using binary encoding. In this example, threshold voltages of the memory cells of the strings of series-connected memory cells 206₀-206₆ might be programmed such that a first grouping of strings of series-connected memory cells 206 (e.g., string of series-connected memory cells 206₀) of the strings of series-connected memory cells 206₀-206₆ might each exhibit a resistance representative of a resistance value R in response to a set of control signals applied to the access lines 202₀-202₃, a second grouping of strings of series-connected memory cells 206 (e.g., strings of series-connected memory cells 206₁ and 206₂) of the strings of series-connected memory cells 206₀-206₆ might exhibit a high impedance in response to the set of control signals applied to the access lines 202₀-202₃, and a third grouping of strings of series-connected memory cells 206 (e.g., strings of series-connected memory cells 206₃-206₆) of the strings of series-connected memory cells 206₀-206₆ might each exhibit a resistance representative of the resistance value of R in response to the set of control signals applied to the access lines 202₀-202₃. In this manner, in response to the set of control signals applied to the access lines 202₀-202₃, the strings of series-connected memory cells 206₀-206₆ might collectively exhibit a resistance value approaching R/5 representative of the digital value 101.

As a further alternative, consider the example where the multiplicand is stored in a binary fashion using thermometric encoding. In this example, threshold voltages of the memory cells of the strings of series-connected memory cells 206₀-206₆ might be programmed such that a first grouping of strings of series-connected memory cells 206 (e.g., strings of series-connected memory cells 206₀-206₄) of the strings of series-connected memory cells 206₀-206₆ might each exhibit a resistance representative of a resistance value R in response to a set of control signals applied to the access lines 202₀-202₃, and a second grouping of strings of series-connected memory cells 206 (e.g., strings of series-connected memory cells 206₅-206₆) of the strings of series-connected memory cells 206₀-206₆ might exhibit a high impedance in response to the set of control signals applied to the access lines 202₀-202₃. In this manner, in response to the set of control signals applied to the access lines 202₀-202₃, the strings of series-connected memory cells 206₀-206₆ might collectively exhibit a resistance value approaching R/5 representative of the digital value 101 (e.g., thermometric value 11111).

FIGS. 8A-8F depict three partial product registers 840, e.g., 840₀-840₂, and one accumulation register 842, each containing a respective six digit registers 844, e.g., 844₀-844₅. Collectively, the partial product registers 840 and accumulation register 842 might correspond to a portion of the MAC register 136. While the example depicts three partial product registers 840, embodiments could include additional partial product registers 840, and might generally include a number of partial product registers 840 greater than or equal to a number of digits of a multiplier to be processed. Similarly, while the example depicts one accumulation register 842, embodiments could include additional accumulation registers, e.g., for storing partial sums. And while the example depicts six digit registers 844, embodiments could include additional digit registers 844, and might generally include a number of digit registers 844 greater than or equal to a number of digits of a multiplicand to be processed, plus a number of digits of a multiplier to be processed.

To obtain the results of FIG. 8A, the common source 216 in FIG. 7 might be connected to a reference potential (e.g., V_{SS}, 0V or ground) through the ADC 730. The voltage level of the common source (Vcs) might thus be at (or near) the reference potential. A voltage level might be applied to the source select line 214 to activate the source select gates 210, a voltage level might be applied to the drain select line 215₀ to activate its corresponding drain select gates 212, and a voltage level might be applied to the drain select lines 2151 and 2152 to deactivate their corresponding drain select gates 212. A voltage level indicative of a first digit of the multiplier, e.g., a most significant digit, might be applied to each of the data lines 204₀ to 204₆. As the first digit of the multiplier is 0, a voltage level V0 might be applied to each of the data lines 204₀ to 204₆. The voltage level V0 might be equal to (or lower than) the voltage level Vcs.

Voltage levels might be applied to the access lines 202 that are configured to activate respective memory cells 208 of NAND strings 206₀ to 206₆ that correspond to a digit of the multiplicand having the first logic level, and to deactivate respective memory cells 208 of NAND strings 206₀ to 206₆ that correspond to a digit of the multiplicand having the second logic level. The voltage levels applied to the access lines 202 might further deactivate at least one corresponding memory cell 208 of each NAND string 206 that does not correspond to any digit of the multiplicand, e.g., the threshold voltages of these memory cells 208 might be higher than a voltage level applied to their corresponding access line, e.g., their threshold voltages might correspond to a digit of the multiplicand having the second logic level.

In the example embodiment, whether the multiplicand is stored in an analog or a binary fashion with binary encoding, or in a binary fashion with thermometric encoding, the access line 202₃ might receive a voltage level configured to activate respective memory cells 208 of NAND strings 206₀ to 206₆ that correspond to a digit of the multiplicand having the first logic level, and to deactivate respective memory cells 208 of NAND strings 206₀ to 206₆ that correspond to a digit of the multiplicand having the second logic level or that do not correspond to any digit of the multiplicand. Concurrently, voltage levels applied to the access lines 202₀-202₂ (e.g., the remaining access lines 202 not storing the multiplicand) might be pass voltages having voltage levels configured to activate their respective memory cells 208 regardless of their corresponding threshold voltages. The voltage level applied to the access line 202₃ might further deactivate at least one memory cell 208 of each NAND string 206 that does not correspond to any digit of the multiplicand, e.g., the threshold voltages of these memory cells 208 might be higher than a voltage level applied to their corresponding access line, e.g., their threshold voltages might correspond to a digit of the multiplicand having the second logic level.

Note that for embodiments storing the multiplicand to more than one memory cell per NAND string 206, each access line 202 that is connected to a memory cell 208 corresponding to a digit of the multiplicand might receive a voltage level configured to activate respective memory cells 208 of NAND strings 206₀ to 206₆ that correspond to a digit of the multiplicand having the first logic level, and to deactivate respective memory cells 208 of NAND strings 206₀ to 206₆ that correspond to a digit of the multiplicand having the second logic level, while remaining access lines 202 might receive the pass voltage.

As the voltage differential (Vds) between the data lines 204 and the common source 216 might be 0V or lower, there might be no expectation of current flow to the ADC 730, which might result in the output of the ADC 730 being a digital value of 000, e.g., having a current flow less than the value A₁ of Table 1. The digital value 000 might then be stored in the digit register 844₀-844₂ of the partial product register 840₀. Digit registers 844 not depicting any value might be considered as each storing the value 0. In FIG. 8B, the result of the first multiply operation might be shifted to the next partial product register 840, e.g., 840₁, and shifted one order to digit registers 844₁-844₃.

To obtain the results of FIG. 8C, the common source 216 in FIG. 7 might be connected to the reference potential through the ADC 730. The voltage level of the common source (Vcs) might thus be at (or near) the reference potential. A voltage level might be applied to the source select line 214 to activate the source select gates 210, a voltage level might be applied to the drain select line 215₀ to activate its corresponding drain select gates 212, and a voltage level might be applied to the drain select lines 215₁ and 215₂ to deactivate their corresponding drain select gates 212. A voltage level indicative of a second digit of the multiplier might be applied to each of the data lines 204₀ to 204₆. As the second digit of the multiplier is 1, a voltage level V1 might be applied to each of the data lines 204₀ to 204₆. Alternatively, data lines 204 corresponding to NAND strings 206 that do not correspond to any digit of the multiplicand might receive the voltage level V0 or other voltage level equal to (or lower than) the voltage level of the common source 216. The voltage level V1 might be higher than the voltage level Ves, such that a voltage differential between the data lines 204 and the common source 216 might be positive.

Voltage levels might be applied to the access lines 202 that are configured to activate respective memory cells 208 of NAND strings 206₀ to 206₆ that correspond to a digit of the multiplicand having the first logic level, and to deactivate respective memory cells 208 of NAND strings 206₀ to 206₆ that correspond to a digit of the multiplicand having the second logic level. The voltage levels applied to the access lines 202 might further deactivate at least one memory cell 208 of each NAND string 206 that does not correspond to any digit of the multiplicand, e.g., the threshold voltages of these memory cells 208 might be higher than a voltage level applied to their corresponding access line, e.g., their threshold voltages might correspond to a digit of the multiplicand having the second logic level.

In the example embodiment, whether the multiplicand is stored in an analog or a binary fashion with binary encoding, or in a binary fashion with thermometric encoding, the access line 202₃ might receive a voltage level configured to activate respective memory cells 208 of NAND strings 206₀ to 206₆ that correspond to a digit of the multiplicand having the first logic level, and to deactivate respective memory cells 208 of NAND strings 206₀ to 206₆ that correspond to a digit of the multiplicand having the second logic level or that do not correspond to any digit of the multiplicand. Concurrently, voltage levels applied to the access lines 202₀-202₂ might be pass voltages configured to activate their respective memory cells 208 regardless of their corresponding threshold voltages.

The voltage differential (Vds) between the data lines 204 and the common source 216 might be positive, and there might be an expectation of current flow to the ADC 730 that is greater than or equal to the current level A₅ and less than the current level A₆, which might result in the output of the ADC 730 being a digital value of 101. The digital value 101 might then be stored in the digit register 844₀-844₂ of the partial product register 840₀. In FIG. 8D, the result of the first multiply operation might be shifted to a next partial product register 840, e.g., 840₂, and shifted one order to digit registers 844₂-844₄, and the result of the second multiply operation might be shifted to a next partial product register 840, e.g., 840₁, and shifted one order to digit registers 844₁-844₃. Note that the shifting of the results of the multiply operations might serve to provide a desired magnitude to their digital values prior to their accumulation.

To obtain the results of FIG. 8E, the process described with reference to FIG. 8C might be repeated. For example, the common source 216 in FIG. 7 might be connected to the reference potential through the ADC 730. The voltage level of the common source (Vcs) might thus be at (or near) the reference potential. A voltage level might be applied to the source select line 214 to activate the source select gates 210, a voltage level might be applied to the drain select line 215₀ to activate its corresponding drain select gates 212, and a voltage level might be applied to the drain select lines 215₁ and 215₂ to deactivate their corresponding drain select gates 212. A voltage level indicative of a third digit of the multiplier, e.g., a least significant digit, might be applied to each of the data lines 204₀ to 204₆. As the third digit of the multiplier is 1, the voltage level V1 might be applied to each of the data lines 204₀ to 204₆.

The access line 202₃ might receive a voltage level configured to activate respective memory cells 208 of NAND strings 206₀ to 206₆ that correspond to a digit of the multiplicand having the first logic level, and to deactivate respective memory cells 208 of NAND strings 206₀ to 206₆ that correspond to a digit of the multiplicand having the second logic level or that do not correspond to any digit of the multiplicand. Concurrently, voltage levels applied to the access lines 202₀-202₂ might be pass voltages configured to activate their respective memory cells 208 regardless of their corresponding threshold voltages.

The voltage differential (Vds) between the data lines 204 and the common source 216 might be positive, and there might be an expectation of current flow to the ADC 730 that is greater than or equal to the current level As and less than the current level A₆, which might result in the output of the ADC 730 being a digital value of 101. The digital value 101 might then be stored in the digit register 844₀-844₂ of the partial product register 840₀.

As an alternative to shifting the digital values one order when shifting to a subsequent partial product register 840, the digital values of the output of the ADC 730 could be directly stored to digit registers indicative of their magnitude. For example, in FIG. 8A, the digital value 000 could have been stored in the digit registers 844₂-844₄ of the partial product register 840₀, and merely shifted down to the partial product register 840₂ without further shifting its magnitude, and in FIG. 8C, the digital value 101 could have been stored in the digit registers 844₁-844₃ of the partial product register 840₀, and merely shifted down to the partial product register 840₁ without further shifting its magnitude. In this manner, the order of applying the digits of the multiplier could be altered as the shifting of the order to the desired magnitude would be independent upon the timing of its application.

In FIG. 8F, the partial product registers 840₀-840₂ might be summed and stored to the accumulation register 842, e.g., in manners well understood in the art, to yield the result 01111 representative of the product of the multiplicand 101 and the multiplier 011. The result stored to the accumulation register 842 might represent the product of an of Matrix A and b₁₁ of Matrix B in FIG. 5, for example. Continuing with this example, the process could be repeated for additional multiplicand/multiplier pairs, e.g., the product of a₁₂ of Matrix A and b₂₁ of Matrix B, the product of a₁₃ of Matrix A and b₃₁ of Matrix B, and the product of a₁₄ of Matrix A and b₄₁ of Matrix B, and these products could be summed to generate cu of Matrix C as described with reference to FIG. 5. In this manner, the operation of the memory could function as a vector-vector unit, e.g., the vector-vector unit 361₁ of FIG. 4 consistent with the foregoing example, to generate the value of one element (e.g., c₁₁) of the result Matrix C.

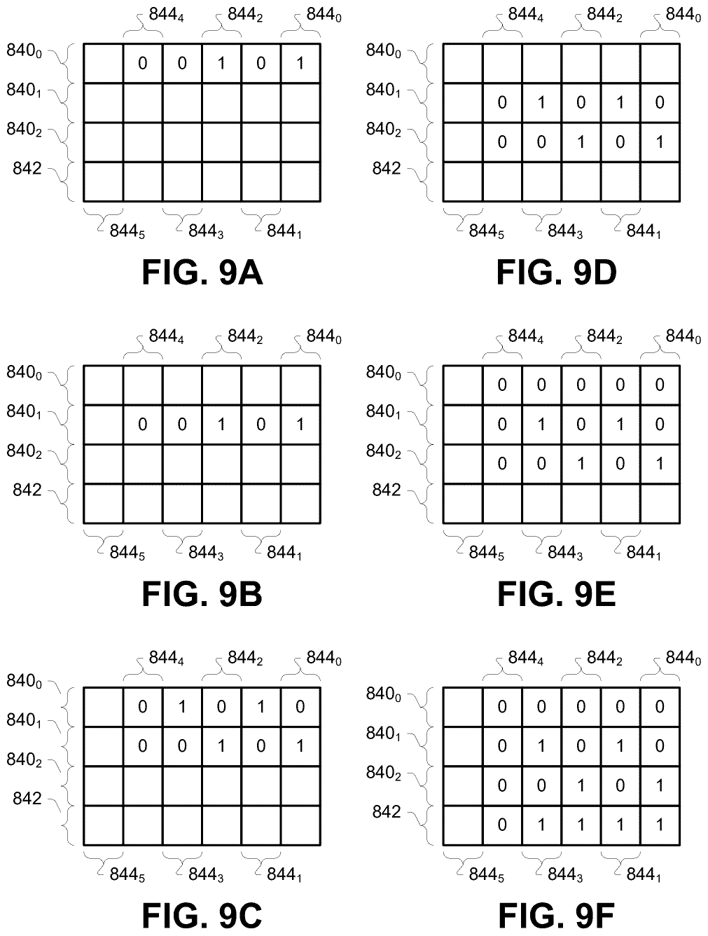

FIGS. 9A-9F depict registers during a multiply-accumulate operation in accordance with another embodiment. FIGS. 9A-9F will be described with reference to FIG. 7. The example of FIGS. 9A-9F might store the multiplicand in either an analog fashion (e.g., as discussed with reference to FIG. 6A), or a binary fashion (e.g., as discussed with reference to FIG. 6B). Voltages indicative of digits of the multiplier might be applied in an analog fashion, e.g., either a voltage indicative of a digit having a logical value of 0, or a respective voltage level representative of a magnitude of a digit having a logical value of 1.

The discussion of carrying out the multiply-accumulate operation will presume the example of storing the multiplicand to memory cells 208 of the strings of series-connected memory cells 206₀-206₆ of FIG. 7 corresponding to the access line 202₃ (e.g., having their control gates connected to the access line 202₃) and to the drain select line 215₀ (e.g., being selectively connected to a respective data line 204 through a drain select gate 212 having its control gate connected to the drain select line 215₀). To simplify the example, the ADC 730 will be described as a five-digit ADC, e.g., having 32 possible digital outputs. In practice, the ADC 730 might be expected to have higher order outputs (e.g., eight-digit, sixteen-digit, or more), and thus much higher granularity.

Table 2 depicts one possible relationship between the digital value of the output of the example ADC 730 for various levels of current flow A₁ to A₃₁ from the common source 216, where A₁<A₂<A₃<A₄<A₅<A₆<A₇<A₈<A₉<A₁₀<A₁₁<A₁₂<A₁₃<A₁₄<A₁₅<A₁₆<A₁₇<A₁₈<A₁₉<A₂₀<A₂₁<A₂₂<A₂₃<A₂₄<A₂₅<A₂₆<A₂₇<A₂₈<A₂₉<A₃₀<A₃₁. Note that absolute values of the current levels A₁-A₃₁ would generally depend on the selected design parameters, e.g., a number of digits of output from the ADC 730, voltages selected for driving access lines 202 and data lines 204, a maximum expected number of NAND strings 206 that might be conducting, etc.

TABLE 2
Digital Value vs Current Flow in Five-Digit ADC

| Amps | | |
|---|---|---|
| Greater Than | | |
| or Equal To | Less Than | Digital Value |
| | A₁ | 00000 |
| A₁ | A₂ | 00001 |
| A₂ | A₃ | 00010 |
| A₃ | A₄ | 00011 |
| A₄ | A₅ | 00100 |
| A₅ | A₆ | 00101 |
| A₆ | A₇ | 00110 |
| A₇ | A₈ | 00111 |
| A₈ | A₉ | 01000 |
| A₉ | A₁₀ | 01001 |
| A₁₀ | A₁₁ | 01010 |
| A₁₁ | A₁₂ | 01011 |
| A₁₂ | A₁₃ | 01100 |
| A₁₃ | A₁₄ | 01101 |
| A₁₄ | A₁₅ | 01110 |
| A₁₅ | A₁₆ | 01111 |
| A₁₆ | A₁₇ | 10000 |
| A₁₇ | A₁₈ | 10001 |
| A₁₈ | A₁₉ | 10000 |
| A₁₉ | A₂₀ | 10011 |
| A₂₀ | A₂₁ | 10100 |
| A₂₁ | A₂₂ | 10101 |
| A₂₂ | A₂₃ | 10110 |
| A₂₃ | A₂₄ | 10111 |
| A₂₄ | A₂₅ | 11000 |
| A₂₅ | A₂₆ | 11001 |
| A₂₆ | A₂₇ | 11010 |
| A₂₇ | A₂₈ | 11011 |
| A₂₈ | A₂₉ | 11100 |
| A₂₉ | A₃₀ | 11101 |
| A₃₀ | A₃₁ | 11110 |
| A₃₁ | | 11111 |

For the example of FIGS. 9A-9F the multiplicand might be the digital value 101, while the multiplier might be the digital value 011. The multiplicand 101 might be stored to the strings of series-connected memory cells 206₀-206₆ as described with reference to FIGS. 8A-8F in either an analog fashion using binary encoding, in a binary fashion using binary encoding, or in a binary fashion using thermometric encoding.

FIGS. 9A-9F depict three partial product registers 840, e.g., 840₀-840₂, and one accumulation register 842, each containing a respective six digit registers 844, e.g., 844₀-844₅. Collectively, the partial product registers 840 and accumulation register 842 might correspond to a portion of the MAC register 136. While the example depicts three partial product registers 840, embodiments could include additional partial product registers 840, and might generally include a number of partial product registers 840 greater than or equal to a number of digits of a multiplier to be processed. Similarly, while the example depicts one accumulation register 842, embodiments could include additional accumulation registers, e.g., for storing partial sums. And while the example depicts six digit registers 844, embodiments could include additional digit registers 844, and might generally include a number of digit registers 844 greater than or equal to a number of digits of a multiplicand to be processed, plus a number of digits of a multiplier to be processed.

While the example of FIGS. 8A-8F began with the most significant digit of the multiplier, the example of FIGS. 9A-9F will be described beginning with the least significant digit of the multiplier. However, the order of applying the digits of the multiplier for the example of FIGS. 9A-9F could be performed in a different order if desired.

To obtain the results of FIG. 9A, the common source 216 in FIG. 7 might be connected to a reference potential (e.g., Vss, 0V or ground) through the ADC 730. The voltage level of the common source (Vcs) might thus be at (or near) the reference potential. A voltage level might be applied to the source select line 214 to activate the source select gates 210, a voltage level might be applied to the drain select line 215₀ to activate its corresponding drain select gates 212, and a voltage level might be applied to the drain select lines 215₁ and 215₂ to deactivate their corresponding drain select gates 212. A voltage level indicative of a first digit of the multiplier, e.g., a least significant digit, might be applied to each of the data lines 204₀ to 204₆. As the first digit of the multiplier is 1 with a magnitude of 2\hat{ }0, a voltage level V1 might be applied to each of the data lines 204₀ to 204₆. Alternatively, data lines 204 corresponding to NAND strings 206 that do not correspond to any digit of the multiplicand might receive the voltage level V0 or other voltage level equal to (or lower than) the voltage level of the common source 216. The voltage level V1 might be higher than the voltage level Vcs, such that a voltage differential between the data lines 204 and the common source 216 might be positive.

Voltage levels might be applied to the access lines 202 that are configured to activate respective memory cells 208 of NAND strings 206₀ to 206₆ that correspond to a digit of the multiplicand having the first logic level, and to deactivate respective memory cells 208 of NAND strings 206₀ to 206₆ that correspond to a digit of the multiplicand having the second logic level. The voltage levels applied to the access lines 202 might further deactivate at least one corresponding memory cell 208 of each NAND string 206 that does not correspond to any digit of the multiplicand, e.g., the threshold voltages of these memory cells 208 might be higher than a voltage level applied to their corresponding access line, e.g., their threshold voltages might correspond to a digit of the multiplicand having the second logic level.

In the example embodiment, whether the multiplicand is stored in an analog or a binary fashion with binary encoding, or in a binary fashion with thermometric encoding, the access line 202₃ might receive a voltage level configured to activate respective memory cells 208 of NAND strings 206₀ to 206₆ that correspond to a digit of the multiplicand having the first logic level, and to deactivate respective memory cells 208 of NAND strings 206₀ to 206₆ that correspond to a digit of the multiplicand having the second logic level or that do not correspond to any digit of the multiplicand. Concurrently, voltage levels applied to the access lines 202₀-202₂ (e.g., the remaining access lines 202 not storing the multiplicand) might be pass voltages having voltage levels configured to activate their respective memory cells 208 regardless of their corresponding threshold voltages. The voltage level applied to the access line 202₃ might further deactivate at least one memory cell 208 of each NAND string 206 that does not correspond to any digit of the multiplicand, e.g., the threshold voltages of these memory cells 208 might be higher than a voltage level applied to their corresponding access line, e.g., their threshold voltages might correspond to a digit of the multiplicand having the second logic level.

Note that for embodiments storing the multiplicand to more than one memory cell per NAND string 206, each access line 202 that is connected to a memory cell 208 corresponding to a digit of the multiplicand might receive a voltage level configured to activate respective memory cells 208 of NAND strings 206₀ to 206₆ that correspond to a digit of the multiplicand having the first logic level, and to deactivate respective memory cells 208 of NAND strings 206₀ to 206₆ that correspond to a digit of the multiplicand having the second logic level, while remaining access lines 202 might receive the pass voltage.

The voltage differential (Vds) between the data lines 204 and the common source 216 might be positive, and there might be an expectation of current flow to the ADC 730 that is greater than or equal to the current level As and less than the current level A₆ of Table 2, which might result in the output of the ADC 730 being a digital value of 00101. The digital value 00101 might then be stored in the digit register 844₀-844₄ of the partial product register 840₀. Digit registers 844 not depicting any value might be considered as each storing the value 0. In FIG. 9B, the result of the first multiply operation might be shifted to the next partial product register 840, e.g., 840₁. Note that there is no need to shift the result to a higher order as the result of the first multiply operation might be representative of its desired magnitude.

To obtain the results of FIG. 9C, the common source 216 in FIG. 7 might be connected to the reference potential through the ADC 730. The voltage level of the common source (Vcs) might thus be at (or near) the reference potential. A voltage level might be applied to the source select line 214 to activate the source select gates 210, a voltage level might be applied to the drain select line 215₀ to activate its corresponding drain select gates 212, and a voltage level might be applied to the drain select lines 215₁ and 215₂ to deactivate their corresponding drain select gates 212. A voltage level indicative of a second digit of the multiplier might be applied to each of the data lines 204₀ to 204₆. As the second digit of the multiplier is 1 with a magnitude of 2\hat{ }1, a voltage level V2 might be applied to each of the data lines 204₀ to 204₆. Alternatively, data lines 204 corresponding to NAND strings 206 that do not correspond to any digit of the multiplicand might receive the voltage level V0 or other voltage level equal to (or lower than) the voltage level of the common source 216.

The voltage level V2 might be higher than the voltage level Ves, such that a voltage differential between the data lines 204 and the common source 216 might be positive. The voltage level V2 might be higher than the voltage level V1. The voltage level V2 might be configured to generate a voltage differential Vds that would be two times (e.g., 2\hat{ }1) a voltage differential representative of the least significant digit of the multiplier. In this manner, the resulting current flow in response to the voltage differential V2-Vcs might have a current level that is two times the current level in response to the voltage differential V1-Vcs, such that its resulting current flow would be representative of its value and magnitude.

Voltage levels might be applied to the access lines 202 that are configured to activate respective memory cells 208 of NAND strings 206₀ to 206₆ that correspond to a digit of the multiplicand having the first logic level, and to deactivate respective memory cells 208 of NAND strings 206₀ to 206₆ that correspond to a digit of the multiplicand having the second logic level. The voltage levels applied to the access lines 202 might further deactivate at least one memory cell 208 of each NAND string 206 that does not correspond to any digit of the multiplicand, e.g., the threshold voltages of these memory cells 208 might be higher than a voltage level applied to their corresponding access line, e.g., their threshold voltages might correspond to a digit of the multiplicand having the second logic level.

In the example embodiment, whether the multiplicand is stored in an analog or a binary fashion with binary encoding, or in a binary fashion with thermometric encoding, the access line 202₃ might receive a voltage level configured to activate respective memory cells 208 of NAND strings 206₀ to 206₆ that correspond to a digit of the multiplicand having the first logic level, and to deactivate respective memory cells 208 of NAND strings 206₀ to 206₆ that correspond to a digit of the multiplicand having the second logic level or that do not correspond to any digit of the multiplicand. Concurrently, voltage levels applied to the access lines 202₀-202₂ might be pass voltages configured to activate their respective memory cells 208 regardless of their corresponding threshold voltages.

The voltage differential (Vds) between the data lines 204 and the common source 216 might be positive, and there might be an expectation of current flow to the ADC 730 that is greater than or equal to the current level A₁₀ and less than the current level A₁₁ of Table 2, which might result in the output of the ADC 730 being a digital value of 01010. The digital value 01010 might then be stored in the digit register 844₀-844₄ of the partial product register 840₀. In FIG. 9D, the result of the first multiply operation might be shifted to a next partial product register 840, e.g., 840₂, and the result of the second multiply operation might be shifted to a next partial product register 840, e.g., 840₁. Note that there is no need to shift the results to a higher order as the results of the first and second multiply operations might be representative of their respective desired magnitudes.

To obtain the results of FIG. 9E, the common source 216 in FIG. 7 might be connected to the reference potential through the ADC 730. The voltage level of the common source (Vcs) might thus be at (or near) the reference potential. A voltage level might be applied to the source select line 214 to activate the source select gates 210, a voltage level might be applied to the drain select line 215₀ to activate its corresponding drain select gates 212, and a voltage level might be applied to the drain select lines 215₁ and 215₂ to deactivate their corresponding drain select gates 212. A voltage level indicative of a third digit, e.g., a most significant digit, of the multiplier might be applied to each of the data lines 204₀ to 204₆. As the third digit of the multiplier is 0, a voltage level V0 might be applied to each of the data lines 204₀ to 204₆. The voltage level V0 might be equal to (or lower than) the voltage level Vcs.

Had the third digit of the multiplier been 1, a voltage level V4 might have been applied to each of the data lines 204₀ to 204₆. The voltage level V4 might be higher than the voltage level Vcs, such that a voltage differential between the data lines 204 and the common source 216 might be positive. The voltage level V4 might be configured to generate a voltage differential Vds that would be four times (e.g., 2\hat{ }2) a voltage differential representative of the least significant digit of the multiplier. In this manner, the resulting current flow in response to the voltage differential V4-Vcs could have a current level that is four times the current level in response to the voltage differential V1-Vcs, such that its resulting current flow would be representative of its value and magnitude.

Voltage levels might be applied to the access lines 202 that are configured to activate respective memory cells 208 of NAND strings 206₀ to 206₆ that correspond to a digit of the multiplicand having the first logic level, and to deactivate respective memory cells 208 of NAND strings 206₀ to 206₆ that correspond to a digit of the multiplicand having the second logic level. The voltage levels applied to the access lines 202 might further deactivate at least one memory cell 208 of each NAND string 206 that does not correspond to any digit of the multiplicand, e.g., the threshold voltages of these memory cells 208 might be higher than a voltage level applied to their corresponding access line, e.g., their threshold voltages might correspond to a digit of the multiplicand having the second logic level.

In the example embodiment, whether the multiplicand is stored in an analog or a binary fashion with binary encoding, or in a binary fashion with thermometric encoding, the access line 202₃ might receive a voltage level configured to activate respective memory cells 208 of NAND strings 206₀ to 206₆ that correspond to a digit of the multiplicand having the first logic level, and to deactivate respective memory cells 208 of NAND strings 206₀ to 206₆ that correspond to a digit of the multiplicand having the second logic level or that do not correspond to any digit of the multiplicand. Concurrently, voltage levels applied to the access lines 202₀-202₂ might be pass voltages configured to activate their respective memory cells 208 regardless of their corresponding threshold voltages.

As the voltage differential (Vds) between the data lines 204 and the common source 216 might be 0V or lower, there might be no expectation of current flow to the ADC 730, which might result in the output of the ADC 730 being a digital value of 00000, e.g., having a current flow less than the value A₁ of Table 2. The digital value 00000 might then be stored in the digit register 844₀-844₄ of the partial product register 840₀.

In FIG. 9F, the partial product registers 840₀-840₂ might be summed, e.g., in manners well understood in the art, to yield the result 01111 representative of the product of the multiplicand 101 and the multiplier 011. The result stored to the accumulation register 842 might represent the product of an of Matrix A and b₁₁ of Matrix B in FIG. 5, for example. Continuing with this example, the process could be repeated for additional multiplicand/multiplier pairs, e.g., the product of a₁₂ of Matrix A and b₂₁ of Matrix B, the product of a₁₃ of Matrix A and b₃₁ of Matrix B, and the product of @14 of Matrix A and b₄₁ of Matrix B, and these products could be summed to generate cu of Matrix c₁₁ as described with reference to FIG. 5. In this manner, the operation of the memory could function as a vector-vector unit, e.g., the vector-vector unit 361₁ of FIG. 4 consistent with the foregoing example, to generate the value of one element (e.g., c₁₁) of the result Matrix C.

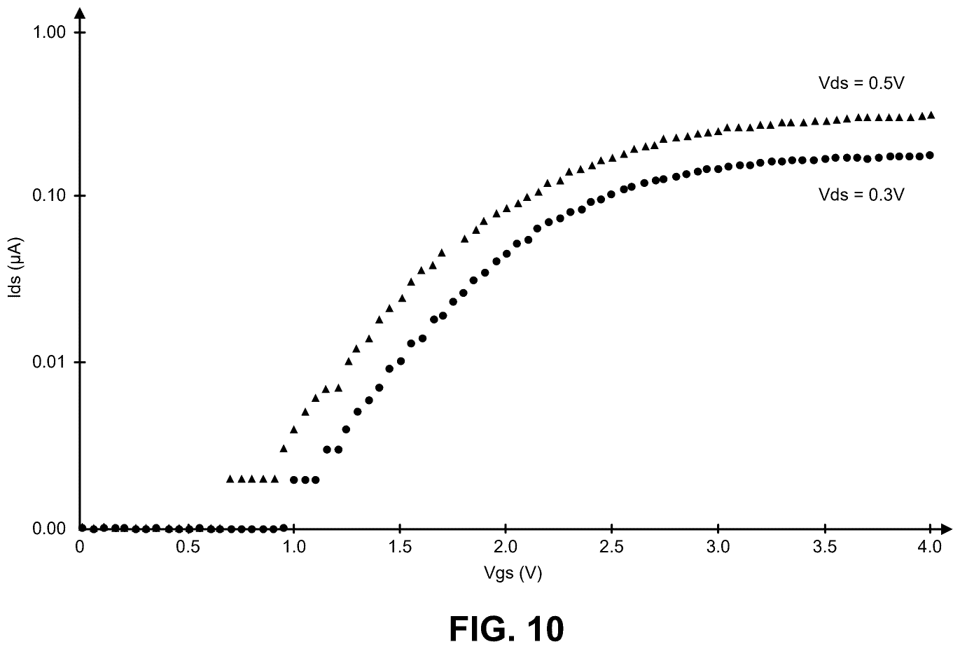

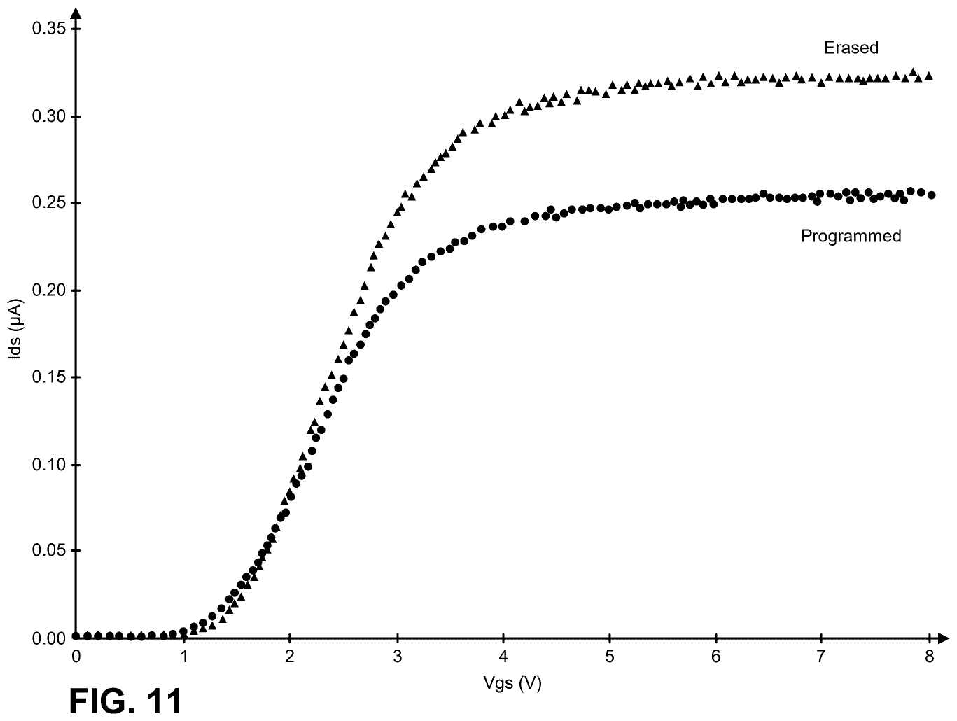

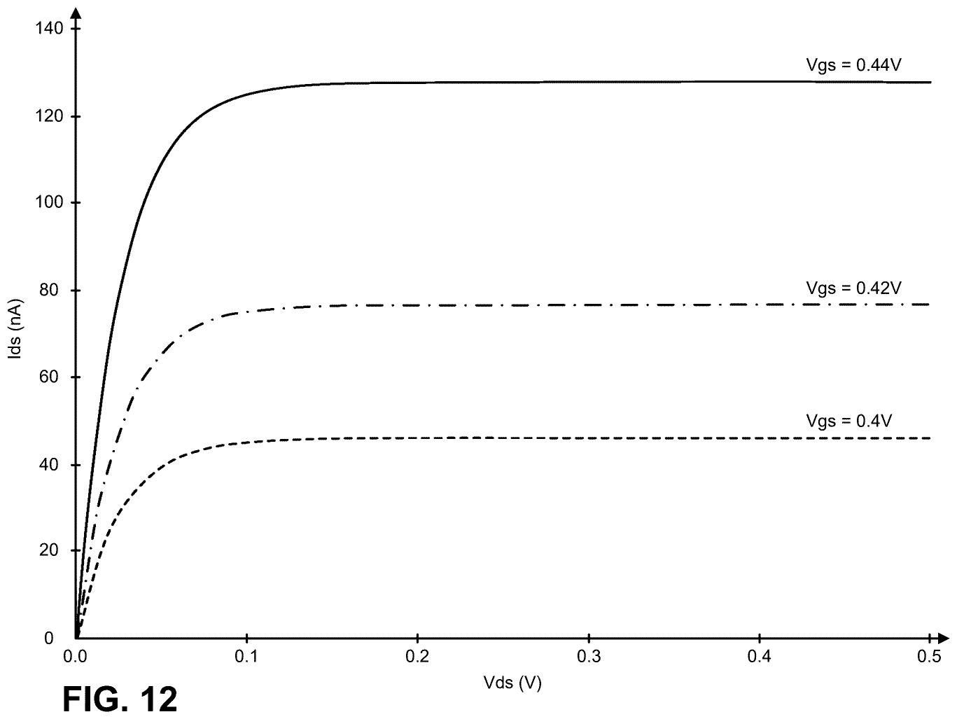

Desired voltage levels for access lines 202 and data lines 204 might be determined experimentally, empirically or through simulation. For example, characterization of conductance (or resistance) of memory cells 208 and NAND strings 206 is generally a routine task given a typically high level of predictability in performance. FIGS. 10-12 might represent characterizations of current flow as a function of relevant variables. For example, FIG. 10 might represent a characterization of cell current (Ids) as a function of access line 202 voltage level (Vgs) for different voltage differential from the data lines 204 to the common source 216 (Vds). FIG. 11 might represent a characterization of cell current (Ids) as a function of access line 202 voltage level (Vgs) for different states of data patterns within a NAND string 206, e.g., erased or programmed, for a particular voltage differential from the data lines 204 to the common source 216. FIG. 12 might represent a characterization of cell current (Ids) as a function of a voltage differential from the data lines 204 to the common source 216 (Vds) for different access line 202 voltage levels (Vgs). With such, or similar, characterizations, knowledge of the number of NAND strings 206 that might be conducting current during a multiply operation, and granularity and current capabilities of available analog-to-digital converters 730, desired voltage levels for access lines 202 and data lines 204 could readily be selected to provide current flows within capabilities of a selected ADC 730.

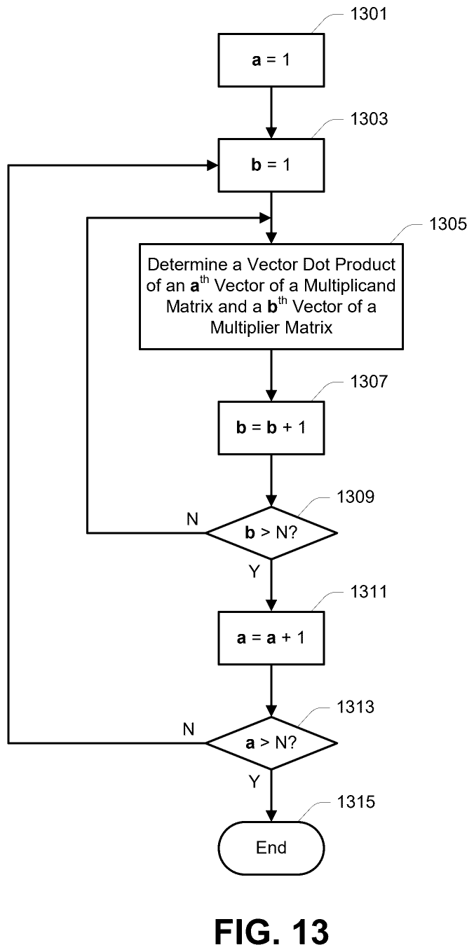

Various embodiments seek to perform the functionality of matrix-matrix units, matrix-vector units, and/or vector-vector units of a DLA. FIG. 13 is a flowchart of a method of operating a memory in accordance with an embodiment. The method might represent actions associated with matrix-matrix units. The method might be in the form of computer-readable instructions, e.g., stored to the instruction registers 128. Such computer-readable instructions might be executed by a controller, e.g., the control logic 116, to cause the relevant components of the memory to perform the method.

At 1301, a value of the variable a might be set to 1. Valid values for the variable a might be any integer value from 1 to N, where N might be equal to a number of rows of a multiplicand matrix, which might be equal to a number of columns of a multiplier matrix. At 1303, a value of the variable b might be set to 1. Valid values for the variable b might be any integer value from 1 to N.

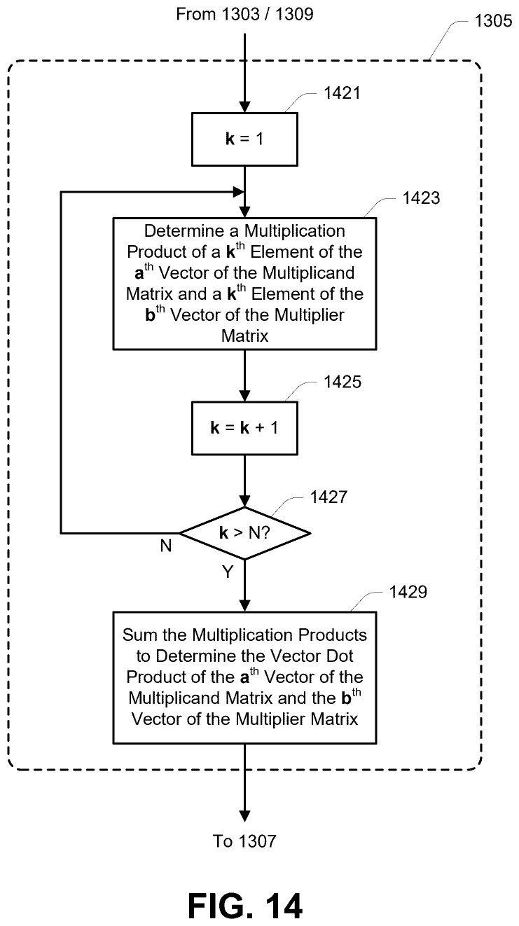

At 1305, a vector dot product of an a^{th} vector of the multiplicand matrix and a b^{th} vector of the multiplier matrix might be determined. Determination of the vector dot product will be described in more detail with reference to subsequent FIGS. 14-16B. The determination of the vector dot product might correspond to the actions of a vector-vector unit 361. For example, with reference to FIG. 4, N might equal 4, and the determination of a vector dot product of the a^{th} vector of the multiplicand matrix and the b^{th} vector of the multiplier matrix might correspond to the actions of a vector-vector unit 361_{ab} for any valid values of the variables a and b. Continuing with this example, the actions of a matrix-vector unit 341ₐ might correspond to the actions of the vector-vector units 361_{ab} for any one valid value of the variable a and all valid values of the variable b, e.g., the actions of a matrix-vector unit 341a might correspond to the actions of the vector-vector units 361ₐ₁, 361ₐ₂, 361ₐ₃, and 361ₐ₄ for any valid value of the variable a. The data register 120 might correspond to the kernel buffers 331, e.g., storing the multiplier vectors (which might be received from an external device, similar to receiving data for programming, or might be read from the array of memory cells 104). The array of memory cells 104 might correspond to the maps banks 351, e.g., storing the multiplicand vectors. The multiplicand might be stored in an analog or a binary fashion with binary encoding, or in a binary fashion with thermometric encoding.

At 1307, the value of the variable b might be incremented by 1. At 1309, it might be determined whether the value of the variable b is greater than N. If not, the process might return to 1305 to determine a vector dot product of the a^{th} vector of the multiplicand matrix and the incremented b^{th} vector of the multiplier matrix. If the value of the variable b is greater than N, the process might proceed to 1311.

At 1311, the value of the variable a might be incremented by 1. At 1313, it might be determined whether the value of the variable a is greater than N. If not, the process might return to 1303 to return the value of the variable b to 1. If the value of the variable a is greater than N, the process might end at 1315.

FIG. 14 is a flowchart of a method of operating a memory in accordance with a further embodiment. The method might represent actions associated with determining a vector dot product at 1305 of FIG. 13. The method might be in the form of computer-readable instructions, e.g., stored to the instruction registers 128. Such computer-readable instructions might be executed by a controller, e.g., the control logic 116, to cause the relevant components of the memory to perform the method.

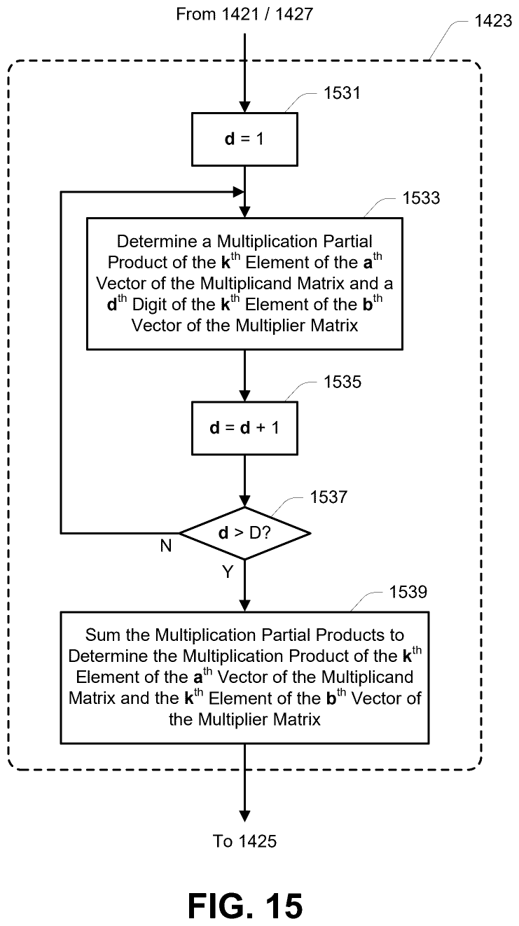

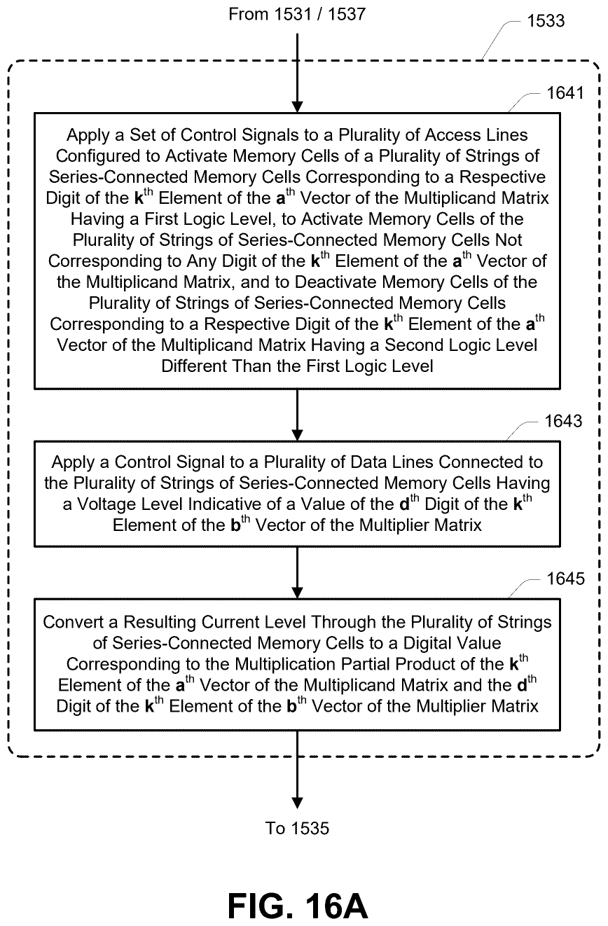

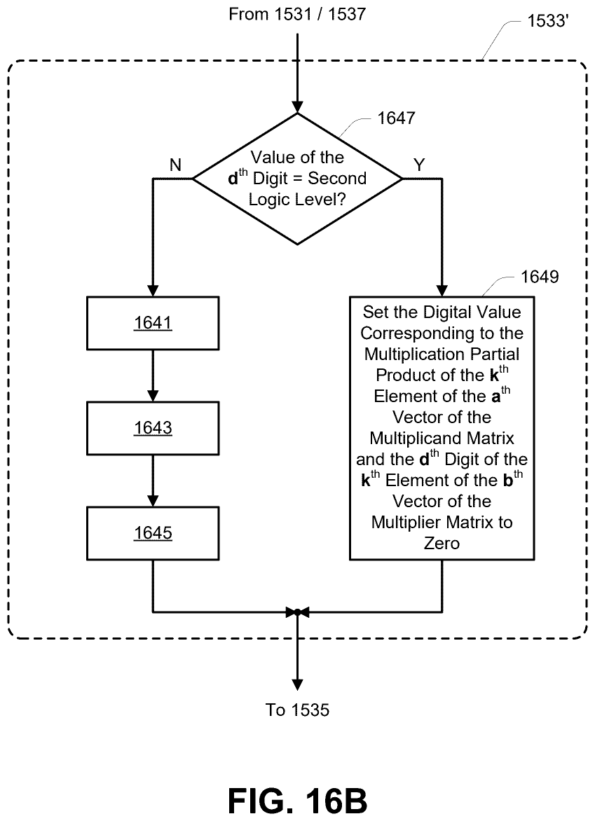

At 1421, a value of the variable k might be set to 1. Valid values for the variable k might be any integer value from 1 to N. At 1423, a multiplication product of a k^{th} element of the a^{th} vector of the multiplicand matrix and a k^{th} element of the b^{th} vector of the multiplier matrix. Determination of the multiplication product will be described in more detail with reference to subsequent FIGS. 15-16B.

At 1425, the value of the variable k might be incremented by 1. At 1427, it might be determined whether the value of the variable k is greater than N. If not, the process might return to 1423 to determine a multiplication product of an incremented k^{th} element of the a^{th} vector of the multiplicand matrix and incremented k^{th} element of the b^{th} vector of the multiplier matrix. If the value of the variable k is greater than N, the process might proceed to 1429. At 1429, the multiplication products for each value of the variable k might be summed to determine the vector dot product of the a^{th} vector of the multiplicand matrix and the b^{th} vector of the multiplier matrix. The process might then proceed to 1307.

FIG. 15 is a flowchart of a method of operating a memory in accordance with a still further embodiment. The method might represent actions associated with determining a multiplication product at 1423 of FIG. 14. The method might be in the form of computer-readable instructions, e.g., stored to the instruction registers 128. Such computer-readable instructions might be executed by a controller, e.g., the control logic 116, to cause the relevant components of the memory to perform the method.

At 1531, a value of the variable d might be set to 1. Valid values for the variable d might be any integer value from 1 to D, where D might be equal to a number of digits of the k^{th} element of the b^{th} vector of the multiplier matrix. At 1533, a multiplication partial product of the k^{th} element of the a^{th} vector of the multiplicand matrix and a d^{th} digit of the k^{th} element of the b^{th} vector of the multiplier matrix. Determination of the multiplication partial product will be described in more detail with reference to subsequent FIGS. 16A-16B.

At 1535, the value of the variable d might be incremented by 1. At 1537, it might be determined whether the value of the variable d is greater than D. If not, the process might return to 1533 to determine a multiplication partial product of the k^{th} element of the a^{th} vector of the multiplicand matrix and the incremented d^{th} digit of the k^{th} element of the b^{th} vector of the multiplier matrix. If the value of the variable d is greater than N, the process might proceed to 1539. At 1539, the multiplication partial products for each value of the variable d might be summed to determine the multiplication product of the k^{th} element of the a^{th} vector of the multiplicand matrix and the k^{th} element of the b^{th} vector of the multiplier matrix. The process might then proceed to 1425.

FIG. 16A is a flowchart of a method of operating a memory in accordance with a still further embodiment. The method might represent actions associated with determining a multiplication partial product at 1533 of FIG. 15. The method might be in the form of computer-readable instructions, e.g., stored to the instruction registers 128. Such computer-readable instructions might be executed by a controller, e.g., the control logic 116, to cause the relevant components of the memory to perform the method.

At 1641, a set of control signals might be applied to a plurality of access lines configured to activate memory cells of a plurality of strings of series-connected memory cells corresponding to a respective digit of the k^{th} element of the a^{th} vector of the multiplicand matrix having a first logic level, to activate memory cells of the plurality of strings of series-connected memory cells not corresponding to any digit of the k^{th} element of the a^{th} vector of the multiplicand matrix having a first logic level, and to deactivate memory cells of the plurality of strings of series-connected memory cells corresponding to a respective digit of the k^{th} element of the a^{th} vector of the multiplicand matrix having a second logic level different than the first logic level. The first logic level might correspond to a digit value of 1, while the second logic level might correspond to a digit value of 0, although such roles might be reversed.

The k^{th} element of the a^{th} vector of the multiplicand matrix might be stored to memory cells of the plurality of strings of series-connected memory cells as described with reference to FIGS. 6A-6B and 7. The set of control signals might include a first subset of control signals applied to a first subset of access lines associated with memory cells storing the k^{th} element of the a^{th} vector of the multiplicand matrix, and might further include a second subset of control signals, e.g., mutually exclusive of the first subset of control signals, applied to a second subset of access lines, e.g., mutually exclusive of the first subset of access lines, that are not associated with memory cells storing the k^{th} element of the a^{th} vector of the multiplicand matrix. Each subset of control signals might include one or more control signals, and each subset of access lines might include one or more access lines. The second subset of control signals, and the second subset of access lines, might be null sets, e.g., each memory cell of one or more strings of series-connected memory cells of the plurality of strings of series-connected memory cells memory cells might correspond to a respective digit of the k^{th} element of the a^{th} vector of the multiplicand matrix.

The first subset of control signals applied to the first subset of access lines might include control signals having a voltage level higher than a threshold voltage of a memory cell storing the first logic level, and lower than a threshold voltage of a memory cell storing the second logic level, such as described with reference to FIGS. 8A-8F and/or 9A-9F. The second subset of control signals applied to the second subset of access lines might include pass voltages, e.g., voltage levels configured to activate memory cells regardless of their stored values, such as described with reference to FIGS. 8A-8F and/or 9A-9F.

At 1643, a control signal might be applied to a plurality of data lines connected to the plurality of strings of series-connected memory cells having a voltage level indicative of a value of the d^{th} digit of the k^{th} element of the b^{th} vector of the multiplier matrix, such as described with reference to FIGS. 8A-8F and/or 9A-9F. Note that the voltage level of the control signal might further be indicative of a magnitude of the d^{th} digit of the k^{th} element of the b^{th} vector of the multiplier matrix, such as described with reference to FIGS. 9A-9F. The voltage level of the control signal might be configured to generate a first voltage differential (e.g., a positive voltage differential) between the plurality of data lines and a common source connected to the plurality of strings of series-connected memory cells in response to the d^{th} digit of the k^{th} element of the b^{th} vector of the multiplier matrix having the first logic level. The voltage level of the control signal might be configured to generate a second voltage differential (e.g., different than the first voltage differential, which might include a zero or negative voltage differential) between the plurality of data lines and the common source in response to the d^{th} digit of the k^{th} element of the b^{th} vector of the multiplier matrix having the second logic level. At 1645, a resulting current level through the plurality of strings of series-connected memory cells might be converted to a digital value (e.g., using an ADC) corresponding to the multiplication partial product of the k^{th} element of the a^{th} vector of the multiplicand matrix and the d^{th} digit of the k^{th} element of the b^{th} vector of the multiplier matrix. The process might then proceed to 1535.

While control signals having voltage levels indicative of values of digits of the k^{th} element of the b^{th} vector of the multiplier matrix having the second logic level might be applied as discussed with reference to the embodiment of FIG. 16A, another embodiment might eliminate application of such control signals to the data lines as discussed with reference to FIG. 16B.

FIG. 16B is a flowchart of a method of operating a memory in accordance with an alternate embodiment. The method might represent actions associated with determining a multiplication partial product at 1533 of FIG. 15. The method might be in the form of computer-readable instructions, e.g., stored to the instruction registers 128. Such computer-readable instructions might be executed by a controller, e.g., the control logic 116, to cause the relevant components of the memory to perform the method.

At 1647, it might be determined whether the value of the d^{th} digit of the k^{th} element of the b^{th} vector of the multiplier matrix has the second logic level. If not, the process of 1641-1645 of FIG. 16A might be performed. If the value of the d^{th} digit of the k^{th} element of the b^{th} vector of the multiplier matrix is determined to have the second logic level, the digital value corresponding to the multiplication partial product of the k^{th} element of the a^{th} vector of the multiplicand matrix and the d^{th} digit of the k^{th} element of the b^{th} vector of the multiplier matrix might be set to zero at 1649, e.g., without applying control signals to the plurality of access lines and/or without applying control signals to the plurality of data lines. Note that, for some embodiments, the control signals applied to the access lines might be maintained during the process of 1533 through all digits of a given vector of the multiplier matrix, and might further be maintained during the process of 1305 through all vectors of the multiplier matrix. The process might then proceed to 1535.

While the flowcharts of FIGS. 13-16B depict one order of processing, other orders could be utilized. For example, instead of the variables a, b, k, and d starting at values of 1 and incrementing to their respective end values of N, N, N, and D, one or more of these variables could start at their respective end values and be decremented to 1 before proceeding at the decision points. Or the processing of individual variables could be performed in a non-sequential order. In addition, processing could be performed concurrently for multiple values of one or more variables. For example, where a first element of a vector of the multiplicand matrix is stored to memory cells of a first block of memory cells (e.g., memory cells selectively connected to a first common source), a second element of the vector of the multiplicand matrix is stored to memory cells of a second block of memory cells (e.g., memory cells selectively connected to a second common source isolated from the first common source), a third element of the vector of the multiplicand matrix is stored to memory cells of a third block of memory cells (e.g., memory cells selectively connected to a third common source isolated from the first common source and the second common source), and so on, the determinations of the multiplication products of these elements and their associated elements of the multiplier matrix could be performed concurrently.

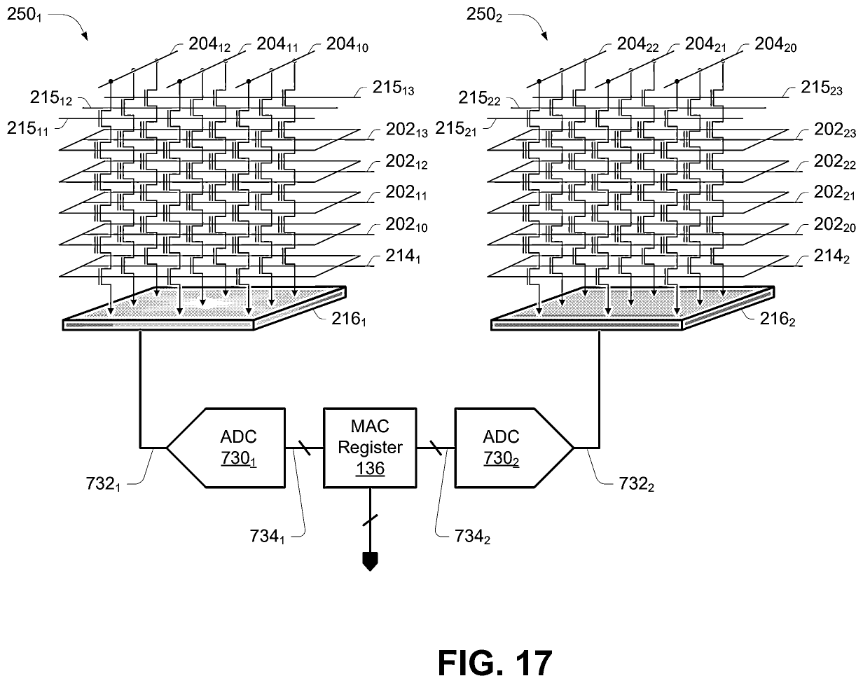

FIG. 17 depicts a portion of an array of memory cells (e.g., two blocks of memory cells 250₁ and 250₂) in accordance with an embodiment. FIG. 17 depicts a first block of memory cells 250₁ having three strings of series-connected memory cells (not labeled in FIG. 17) including memory cells (not labeled in FIG. 17) selectively connected to data lines 204₁₀-204₁₂ through select gates (not labeled in FIG. 17) responsive to a control signal applied to select line 215₁₁ and selectively connected to a common source 216₁ through select gates (not labeled in FIG. 17) responsive to a control signal applied to select line 214₁, three strings of series-connected memory cells (not labeled in FIG. 17) including memory cells (not labeled in FIG. 17) selectively connected to data lines 204₁₀-204₁₂ through select gates (not labeled in FIG. 17) responsive to a control signal applied to select line 215₁₂ and selectively connected to the common source 216₁ through select gates (not labeled in FIG. 17) responsive to the control signal applied to select line 214₁, and three strings of series-connected memory cells (not labeled in FIG. 17) including memory cells (not labeled in FIG. 17) selectively connected to data lines 204₁₀-204₁₂ through select gates (not labeled in FIG. 17) responsive to a control signal applied to select line 21513 and selectively connected to the common source 216₁ through select gates (not labeled in FIG. 17) responsive to the control signal applied to select line 214₁.

FIG. 17 further depicts a second block of memory cells 250₂ having three strings of series-connected memory cells (not labeled in FIG. 17) including memory cells (not labeled in FIG. 17) selectively connected to data lines 204₂₀-204₂₂ through select gates (not labeled in FIG. 17) responsive to a control signal applied to select line 215₂₁ and selectively connected to a common source 216₂ through select gates (not labeled in FIG. 17) responsive to a control signal applied to select line 214₂, three strings of series-connected memory cells (not labeled in FIG. 17) including memory cells (not labeled in FIG. 17) selectively connected to data lines 204₂₀-204₂₂ through select gates (not labeled in FIG. 17) responsive to a control signal applied to select line 21522 and selectively connected to the common source 216₂ through select gates (not labeled in FIG. 17) responsive to the control signal applied to select line 214₂, and three strings of series-connected memory cells (not labeled in FIG. 17) including memory cells (not labeled in FIG. 17) selectively connected to data lines 204₂₀-204₂₂ through select gates (not labeled in FIG. 17) responsive to a control signal applied to select line 215₂₃ and selectively connected to the common source 216₂ through select gates (not labeled in FIG. 17) responsive to the control signal applied to select line 214₂.

The common source 216₁ might be connected to an input 732₁ of an analog-to-digital converter (ADC) 730₁. An output 734₁ of the ADC 730₁ might include a number of signal lines, each configured to provide a respective digital signal having one of two logic levels, e.g., either a “1” or a “0” logic level. The ADC 730₁ might be configured as described with reference to the ADC 730 of FIG. 7. The common source 216₂ might be connected to an input 732₂ of an analog-to-digital converter (ADC) 730₂. An output 734₂ of the ADC 730₂ might include a number of signal lines, each configured to provide a respective digital signal having one of two logic levels, e.g., either a “1” or a “0” logic level. The ADC 730₂ might be configured as described with reference to the ADC 730 of FIG. 7. The outputs 734₁ and 734₂ of the ADCs 730₁ and 730₂, respectively, might be connected to the MAC register 136, e.g., to respective portions of the MAC register 136, to store their multiplication partial products. It will be apparent that additional blocks of memory cells 250 could have their respective sources 216 connected to respective ADCs 730 that are connected to respective portions of the MAC register 136 in order to increase the parallelism of performing multiple multiply operations concurrently.

In addition, the embodiment of FIG. 17 could also be used to increase a number of strings of series-connected memory cells that could be used to store elements of a vector of the multiplicand matrix. For example, a first subset of digits (e.g., less significant digits) of an element of a vector of the multiplicand matrix might be stored to memory cells of the block of memory cells 250₂, and a second subset of digits (e.g., more significant digits) of the element of the vector of the multiplicand matrix might be stored to memory cells of the block of memory cells 250₁. The same control signals might be applied to data lines 204 of both blocks of memory cells 250, respective current levels could be converted by the ADCs 730, and the resulting values could be stored to respective portions of the MAC register 136 for subsequent summation.

### CONCLUSION

Although specific embodiments have been illustrated and described herein, it will be appreciated by those of ordinary skill in the art that any arrangement that is calculated to achieve the same purpose might be substituted for the specific embodiments shown. Many adaptations of the embodiments will be apparent to those of ordinary skill in the art. Accordingly, this application is intended to cover any adaptations or variations of the embodiments.

What is claimed is:

1. A memory, comprising:
a plurality of data lines;
a common source;
a plurality of strings of series-connected memory cells, wherein each string of series-connected memory cells of the plurality of strings of series-connected memory cells is selectively connected to a respective data line of the plurality of data lines, and is selectively connected to the common source, and wherein each string of series-connected memory cells of the plurality of strings of series-connected memory cells corresponds to a respective digit of a plurality of digits of a multiplicand;
a plurality of access lines, wherein each access line of the plurality of access lines is connected to a control gate of a respective memory cell of each string of series-connected memory cells of the plurality of strings of series-connected memory cells; and
a controller configured to cause the memory to:
for each digit of a plurality of digits of a multiplier:
generate a respective current flow through the plurality of strings of series-connected memory cells having a respective current level indicative of a value of that digit of the plurality of digits of the multiplier times the multiplicand; and
convert the respective current level for that digit of the plurality of digits of the multiplier to a respective digital value indicative of the value and a magnitude of that digit of the plurality of digits of the multiplier times the multiplicand; and
sum the respective digital value of each digit of the plurality of digits of the multiplier.

2. The memory of claim 1, wherein a number of strings of series-connected memory cells of the plurality of strings of series-connected memory cells corresponding to a least significant digit of the plurality of digits of the multiplicand is equal to a number of strings of series-connected memory cells of the plurality of strings of series-connected memory cells corresponding to each remaining digit of the plurality of digits of the multiplicand.

3. The memory of claim 2, wherein each string of series-connected memory cells of the plurality of strings of series-connected memory cells has a respective subset of memory cells corresponding to its respective digit of the plurality of digits of the multiplicand, and wherein the respective subset of memory cells of the number of strings of series-connected memory cells of the plurality of strings of series-connected memory cells corresponding to the least significant digit of the plurality of digits of the multiplicand have threshold voltages higher than threshold voltages of the respective subset of memory cells of the number of strings of series-connected memory cells of the plurality of strings of series-connected memory cells corresponding to a more significant digit of the plurality of digits of the multiplicand.

4. The memory of claim 3, wherein a magnitude of the more significant digit of the plurality of digits of the multiplicand is 2\hat{ }N times a magnitude of the least significant digit of the plurality of digits of the multiplicand, and wherein the threshold voltages of the respective subset of memory cells of the number of strings of series-connected memory cells of the plurality of strings of series-connected memory cells corresponding to the least significant digit of the plurality of digits of the multiplicand are configured to generate a resistance in response to a set of control signals applied to the plurality of access lines that is 2\hat{ }N times a resistance generated by the threshold voltages of the respective subset of memory cells of the number of strings of series-connected memory cells of the plurality of strings of series-connected memory cells corresponding to the more significant digit of the plurality of digits of the multiplicand in response to the set of control signals applied to the plurality of access lines.

5. The memory of claim 1, wherein a number of strings of series-connected memory cells of the plurality of strings of series-connected memory cells corresponding to a least significant digit of the plurality of digits of the multiplicand is different than a number of strings of series-connected memory cells of the plurality of strings of series-connected memory cells corresponding to a more significant digit of the plurality of digits of the multiplicand.

6. The memory of claim 1, wherein a magnitude of the more significant digit of the plurality of digits of the multiplicand is 2\hat{ }N times a magnitude of the least significant digit of the plurality of digits of the multiplicand, and wherein the number of strings of series-connected memory cells of the plurality of strings of series-connected memory cells corresponding to the more significant digit of the plurality of digits of the multiplicand is 2\hat{ }N times the number of strings of series-connected memory cells of the plurality of strings of series-connected memory cells corresponding to the least significant digit of the plurality of digits of the multiplicand.

7. The memory of claim 1, wherein the controller being configured to cause the memory to generate a current flow through the plurality of strings of series-connected memory cells comprises the controller being configured to cause the memory to:
for each string of series-connected memory cells of the plurality of strings of series-connected memory cells whose respective digit of the plurality of digits of the multiplicand has a first logic level, activate each memory cell of that string of series-connected memory cells; and
for each string of series-connected memory cells of the plurality of strings of series-connected memory cells whose respective digit of the plurality of digits of the multiplicand has a second logic level different than the first logic level, deactivate each memory cell of that string of series-connected memory cells.

8. A memory, comprising:
a plurality of data lines;
a common source;
a multiply-accumulate (MAC) register comprising a plurality of partial product registers and an accumulation register;
an analog-to-digital converter (ADC) having an input connected to the common source, and having an output connected to the MAC register;
a plurality of strings of series-connected memory cells, wherein each string of series-connected memory cells of the plurality of strings of series-connected memory cells is selectively connected to a respective data line of the plurality of data lines, and is selectively connected to the common source, and wherein each string of series-connected memory cells of the plurality of strings of series-connected memory cells corresponds to a respective digit of a corresponding element of a corresponding vector of a multiplicand matrix having N vectors, where N is an integer value greater than or equal to 1;
a plurality of access lines, wherein each access line of the plurality of access lines is connected to a control gate of a respective memory cell of each string of series-connected memory cells of the plurality of strings of series-connected memory cells; and
a controller configured to cause the memory to:
for an element of one or more elements of a first vector of the multiplicand matrix:
generate a current flow through the plurality of strings of series-connected memory cells having a current level indicative of a value of the element of the first vector times a digit of a multiplier having one or more digits; and
convert the current level for the element of the first vector to a respective digital value indicative of the value and a magnitude of the element of the first vector times the digit of the multiplier.

9. The memory of claim 8, wherein the digit of the multiplier is a digit of an element of a vector of a multiplier matrix, wherein the multiplier matrix has N vectors, and wherein the controller is further configured to cause the memory to:
for each integer value of a=1 to N:
for each integer value of b=1 to N:
determine a vector dot product of an a^{th} vector of the multiplicand matrix and a b^{th} vector of the multiplier matrix;
wherein the controller being configured to cause the memory to determine the vector dot product of the a^{th} vector of the multiplicand matrix and the b^{th} vector of the multiplier matrix comprises the controller being configured to cause the memory to determine respective multiplication products for each element of one or more elements of the a^{th} vector of a multiplicand matrix and its corresponding element of one or more elements of the b^{th} vector of the multiplier matrix, and summing the respective multiplication products;
wherein the controller being configured to cause the memory to determine the respective multiplication product for a selected element of the a^{th} vector of the multiplicand matrix and its corresponding element of the one or more elements of the b^{th} vector of the multiplier matrix comprises the controller being configured to cause the memory to determine a respective multiplication partial product of the selected element of the a^{th} vector of the multiplicand matrix and each digit of its corresponding element of the b^{th} vector of the multiplier matrix, and summing the respective multiplication partial products; and
wherein the controller being configured to cause the memory to determine the respective multiplication partial product of the selected element of the a^{th} vector of the multiplicand matrix and a selected digit of its corresponding element of the b^{th} vector of the multiplier matrix comprises the controller being configured to cause the memory to:
generate a current flow through the plurality of strings of series-connected memory cells having a respective current level indicative of a value of the selected element of the a^{th} vector of the multiplicand matrix times the selected digit of its corresponding element of the b^{th} vector of the multiplier matrix; and
convert the respective current level for the selected element of the a^{th} vector of the multiplicand matrix and the selected digit of its corresponding element of the b^{th} vector of the multiplier matrix to a respective digital value indicative of the value and a magnitude of the selected element of the a^{th} vector of the multiplicand matrix times the selected digit of its corresponding element of the b^{th} vector of the multiplier matrix.

10. The memory of claim 9, wherein each vector of the multiplicand matrix has N elements, wherein each vector of the multiplier matrix has N elements, and wherein the controller being configured to cause the memory to determine the vector dot product of the a^{th} vector of the multiplicand matrix and the b^{th} vector of the multiplier matrix comprises the controller being configured to cause the memory to:
for each integer value of k=1 to N:
determine a multiplication product of a k^{th} element of the a^{th} vector of the multiplicand matrix and a corresponding k^{th} element of the b^{th} vector of the multiplier matrix; and
sum the multiplication products for the N elements of the a^{th} vector of the multiplicand matrix and their corresponding elements of the b^{th} vector of the multiplier matrix.

11. The memory of claim 10, wherein the controller being configured to cause the memory to determine the multiplication product of the k^{th} element of the a^{th} vector of the multiplicand matrix and the k^{th} element of the b^{th} vector of the multiplier matrix comprises the controller being configured to cause the memory to:
for each integer value of d=1 to D, wherein D is equal to a number of digits of the corresponding k^{th} element of the b^{th} vector of the multiplier matrix:
determine a multiplication partial product of the k^{th} element of the a^{th} vector of the multiplicand matrix and a d^{th} digit of the k^{th} element of the b^{th} vector of the multiplier matrix; and
sum the multiplication partial products for the D digits of the k^{th} element of the b^{th} vector of the multiplier matrix and the k^{th} element of the a^{th} vector of the multiplicand matrix.

12. The memory of claim 11, wherein the k^{th} element of the a^{th} vector of the multiplicand matrix corresponds to the selected element of the a^{th} vector of the multiplicand matrix, wherein the d^{th} digit of the k^{th} element of the b^{th} vector of the multiplier matrix corresponds to the selected digit of the element of the b^{th} vector of the multiplier matrix corresponding to the selected element of the a^{th} vector of the multiplicand matrix, and wherein the controller being configured to cause the memory to determine the multiplication partial product of the selected element of the a^{th} vector of the multiplicand matrix and the selected digit of its corresponding element of the b^{th} vector of the multiplier matrix comprises the controller being configured to cause the memory to:
apply a set of control signals to the plurality of access lines configured to activate memory cells of the plurality of strings of series-connected memory cells corresponding to a respective digit of the selected element of the a^{th} vector of the multiplicand matrix having a first logic level, to activate memory cells of the plurality of strings of series-connected memory cells not corresponding to any digit of the selected element of the a^{th} vector of the multiplicand matrix, and to deactivate memory cells of the plurality of strings of series-connected memory cells corresponding to a respective digit of the selected element of the a^{th} vector of the multiplicand matrix having a second logic level different than the first logic level;
apply a control signal to the plurality of data lines connected to the plurality of strings of series-connected memory cells having a voltage level indicative of a value of the selected digit of the corresponding element of the b^{th} vector of the multiplier matrix; and
convert a resulting current level received at the input of the ADC to a digital value corresponding to the multiplication partial product of the selected element of the a^{th} vector of the multiplicand matrix and the selected digit of the corresponding element of the b^{th} vector of the multiplier matrix.

13. The memory of claim 12, wherein the selected digit of the corresponding element of the b^{th} vector of the multiplier matrix has the first logic level.

14. The memory of claim 12, wherein the control signal applied to the plurality of data lines has a voltage level indicative of both the value and a magnitude of the selected digit of the corresponding element of the b^{th} vector of the multiplier matrix.

15. A memory, comprising:
a plurality of data lines;
a common source;
a multiply-accumulate (MAC) register comprising a plurality of partial product registers and an accumulation register;
an analog-to-digital converter (ADC) having an input connected to the common source, and having an output connected to the MAC register;
a plurality of strings of series-connected memory cells, wherein each string of series-connected memory cells of the plurality of strings of series-connected memory cells is selectively connected to a respective data line of the plurality of data lines, and is selectively connected to the common source, and wherein each string of series-connected memory cells of the plurality of strings of series-connected memory cells corresponds to a respective digit of a plurality of digits of a multiplicand;
a plurality of access lines, wherein each access line of the plurality of access lines is connected to a control gate of a respective memory cell of each string of series-connected memory cells of the plurality of strings of series-connected memory cells; and
a controller configured to cause the memory to:
apply a set of control signals to the plurality of access lines configured to activate memory cells of the plurality of strings of series-connected memory cells corresponding to a respective digit of the multiplicand having a first logic level, to activate memory cells of the plurality of strings of series-connected memory cells not corresponding to any digit of the multiplicand, and to deactivate memory cells of the plurality of strings of series-connected memory cells corresponding to a respective digit of the multiplicand having a second logic level different than the first logic level;
while the plurality of strings of series-connected memory cells are connected to the common source, apply a control signal to the plurality of data lines connected to the plurality of strings of series-connected memory cells having a voltage level indicative of a value of a digit of a multiplier; and
convert a current level at the input of the ADC resulting from applying the set of control signals to the plurality of access lines and applying the control signal to the plurality of data lines while the plurality of strings of series-connected memory cells are connected to the common source and to the input of the ADC to a respective digital value corresponding to a value of the multiplicand times the digit of the multiplier.

16. The memory of claim 15, wherein the multiplier has D digits, and wherein the controller is further configured to cause the memory to:
for each integer value of d=1 to D:
in response to the d^{th} digit of the multiplier having the first logic level:
apply a set of control signals to the plurality of access lines configured to activate memory cells of the plurality of strings of series-connected memory cells corresponding to a respective digit of the multiplicand having the first logic level, to activate memory cells of the plurality of strings of series-connected memory cells not corresponding to any digit of the multiplicand, and to deactivate memory cells of the plurality of strings of series-connected memory cells corresponding to a respective digit of the multiplicand having a second logic level different than the first logic level;
while the plurality of strings of series-connected memory cells are connected to the common source, apply a respective control signal to the plurality of data lines connected to the plurality of strings of series-connected memory cells having a voltage level indicative of a value of the d^{th} digit of the multiplier;
convert a respective current level at the input of the ADC resulting from applying the set of control signals to the plurality of access lines and applying the control signal to the plurality of data lines while the plurality of strings of series-connected memory cells are connected to the common source and to the input of the ADC to a respective digital value corresponding to a respective multiplication partial product of the multiplicand and the d^{th} digit of the multiplier; and
store the respective multiplication partial product of the multiplicand and the d^{th} digit of the multiplier to a respective partial product register of the plurality of partial product registers of the MAC register; and
sum the plurality of partial product registers of the MAC register and store the sum to the accumulation register of the MAC register.

17. The memory of claim 16, wherein the controller being configured to cause the memory to perform actions in response to the d^{th} digit of the multiplier having the first logic level comprises the controller being configured to cause the memory to perform the actions in response to the d^{th} digit of the multiplier having the first logic level or having the second logic level.

18. The memory of claim 16, wherein the controller is further configured to cause the memory to:
in response to the d^{th} digit of the multiplier having the second logic level, store a zero to a respective partial product register of the plurality of partial product registers of the MAC register.

19. The memory of claim 18, wherein the controller being configured to cause the memory to store the zero to the respective partial product register comprises the controller being configured to cause the memory to store the zero to the respective partial product register without applying a respective control signal to the plurality of data lines connected to the plurality of strings of series-connected memory cells having a voltage level indicative of a value of the d^{th} digit of the multiplier having the second logic level.

20. The memory of claim 19, wherein the controller being configured to cause the memory to store the zero to the respective partial product register without applying the respective control signal to the plurality of data lines connected to the plurality of strings of series-connected memory cells further comprises the controller being configured to cause the memory to store the zero to the respective partial product register without applying the set of control signals to the plurality of access lines.
